(19) United States
(12) Patent Application Publication
(10) Pub. No.: US 2010/0031991 A1
(43) Pub. Date: Feb. 11, 2010

(54) CONCENTRATING PHOTOVOLTAIC GENERATION SYSTEM

(75) Inventors: Masataka MOCHIZUKI, Tokyo (JP); Koichi MASHIKO, Tokyo (JP); Thang NGUYEN, Tokyo (JP); Ahamad JALILVAND, Tokyo (JP); Aliakbar AKBARZADEH, Tokyo (JP); Randeep SINGH, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Fujikura Ltd., Tokyo (JP)

(21) Appl. No.: 12/536,135

(22) Filed: Aug. 5, 2009

(30) Foreign Application Priority Data
Aug. 7, 2008 (JP) 2008-204738
Mar. 12, 2009 (JP) 2009-58902

(51) Int. Cl. H01L 35/00; H01L 31/00

(52) U.S. Cl. 136/206; 136/259

(57) ABSTRACT

A concentrating photovoltaic generation system including a photovoltaic generator which converts solar light into electric power, a reflector panel which concentrates solar light onto the photovoltaic generator, and a radiation cooling mechanism to which heat is transmitted from the photovoltaic generator and from which heat is radiated, thus cooling the photovoltaic generator.

The present invention claims the benefit of Japanese Patent Applications No. 2008-204738 filed on Aug. 7, 2008 and No. 2009-58902 filed on Mar. 12, 2009 with the Japanese Patent Office, the disclosures of which are incorporated herein by reference in their entirety.

### BACKGROUND

1. Field of the Invention

The present invention relates to a concentrating photovoltaic generation system for generating electric energy by concentrating solar light to a photovoltaic generator to convert the solar light into electric energy.

2. Discussion of the Related Art

Photovoltaic power generation technology for converting solar energy into electricity is well-known in the art, and solar energy can be obtained from the sun substantially perpetually free of cost.

A photoelectric converter converts solar energy into electric power. When the solar energy is converted into electricity, the solar energy is also partially converted into thermal energy. The resultant thermal energy raises a temperature of the photoelectric converter, and an efficiency of photoelectric conversion is thereby degraded. In addition, since a density of the solar energy is low, the solar light has to be concentrated onto a photoelectric converter so as to improve generation efficiency. Thus, an amount of the thermal energy per unit area in the photovoltaic generator is also increased as a result of concentrating the solar light to the photoelectric converter. The conversion efficiency of the photoelectric converter is also degraded by this temperature rise.

In order solve the above-mentioned problem, an amount of the heat on the photoelectric converter has to be reduced, that is, the photoelectric converter has to be cooled. For example, according to the solarlight power generating system disclosed in Japanese Patent Laid-Open No. 2003-70273 a thermal storage means is disposed on a back surface of a solar cell. The solarlight converted into heat without being converted into electricity by a photoelectric converter is stored in the thermal storage means, and the heat stored in the thermal storage means is then converted into electricity. Thus, a conversion efficiency of the solar energy can be improved in the entire system while suppressing temperature rise of the solar cell. That is, according to the teachings of Japanese Patent Laid-Open No. 2003-70273, photoelectric conversion and thermoelectric conversion are combined to improve the conversion efficiency of the solar energy. According to the system taught by Japanese Patent Laid-Open No. 2003-70273, a temperature rise of the photoelectric converter is thus suppressed so that the photoelectric conversion efficiency will not be degraded.

Japanese Patent Laid-Open No. 2006-90659 discloses a solar system and the operating method of solar system, program and recording medium. According to the teachings of Japanese Patent Laid-Open No. 2006-90659, a first heat storage part is installed on the back side of the solar battery panel, and a second heat storage part is insulated on a position where the second heat storage part is not directly influenced by sunlight and is insulated from the atmosphere. In order to minimize a temperature rise of the solar battery panel, a heat storage material is moved by a pump between the first and the second heat storage parts in accordance with the temperature rise of the solar battery panel when the temperature of the solar battery panel is raised by the sunlight. Thus, according to the teachings of Japanese Patent Laid-Open No. 2006-90659, the temperature rise of the solar battery panel is controlled in accordance of the intensity of sun radiation, therefore, the conversion efficiency of the solar energy can be improved.

Japan Patent Laid-Open No. 2001-178163 discloses method and apparatus for power generation using solar heat. According to the teachings of Japan Patent Laid-Open No. 2001-178163, a solar energy concentrated to increase energy density thereof is used as a heat source. The heat is transmitted to a Peltier element by a heat pipe thereby generating electricity. That is, the apparatus and method of Japan Patent Laid-Open No. 2001-178163 are adapted to utilize the heat which otherwise disturbs photoelectric conversion. Thus, the apparatus and method of Japan Patent Laid-Open No. 2001-178163 are adapted to generate electricity by thermoelectric conversion, and are therefore capable of preventing deterioration of the conversion efficiency by the heat.

According to the solar energy collector disclosed in Japanese Patent No. 58-53261, a container of a heat pipe is made of a solar light permeable material such as glass or plastic, and a generating element is encapsulated in the container together with a working fluid and a wick. According to the teachings of Japanese Patent No. 58-53261, the heat which would otherwise degrade the photoelectric conversion efficiency is therefore transported promptly so that the deterioration of the conversion efficiency by the heat can be prevented.

According to the solar energy converter disclosed in Japanese Patent No. 4-69438, a semiconductor film cell, and a heat absorbing layer absorbing solar light penetrating through the film cell thereby converting the solar light into heat, are formed on a light transmissive substrate. The heat of the heat absorbing layer is transported by a heat pipe. The conversion efficiency of the solar energy is thus improved according to Japanese Patent No. 4-69438.

According to the solar heat pump system disclosed in Japanese Patent Laid-Open No. 2005-195187, a solar heat conduction part such as a heat conducting plate or a heat pipe is arranged on the reverse side of the solar battery, so as to suppress temperature rise of the solar battery and to equalize the temperature of the solar battery. The solar heat conduction part is connected to a cooling conduit holding a cooling medium in a heat transmittable manner. Therefore, according to the teachings of Japanese Patent Laid-Open No. 2005-195187, photoelectric conversion efficiency will not be degraded by the heat so that the solar energy can be converted efficiency.

According to the heat collecting device for solar battery disclosed in Japanese Patent Laid-Open No. 9-96451, a heat collecting device such as a heat pipe is arranged on the back side of a solar battery, and temperature of the solar battery is transmitted through the heat pipe. According to the teachings of Japanese Patent Laid-Open No. 9-96451, therefore, temperature rise of the solar battery can be suppressed and photoelectric conversion efficiency will not be degraded by the heat.

According to the radiation cooling device disclosed in Japanese Patent Laid-Open No. 61-134553, an inner space of an insulating container is divided into two chambers by a radiator having an amorphous solar cell, and a means for opening and closing is arranged in a lower chamber in which a heat exchange means is arranged. Thus, the radiation cooling device taught by Japanese Patent Laid-Open No. 61-134553 is adapted to cool the solar cell by the radiator. Japanese Patent Laid-Open No. 58-83168 also discloses a radiation cooling device adapted to perform radiative cooling.

Thus, all of the systems disclosed in Japanese Patent Laid-Open No. 2003-70273, Japanese Patent Laid-Open No. 2006-90659, Japanese Patent Laid-Open No. 2001-178163, Japanese Patent No. 58-53261, Japanese Patent No. 4-69438, Japanese Patent Laid-Open No. 2005-195187 and Japanese Patent Laid-Open No. 9-96451 are adapted to suppress the temperature rise of the photoelectric converter by transporting the heat of the photoelectric converter to the thermal storage by a heat transport means such as a heat pipe or a pump. In fact, storing the heat raising the temperature of the photoelectric converter is effective to minimize deterioration of the photoelectric conversion efficiency. However, such configuration for storing the heat may be incapable of cooling the photoelectric converter positively. Meanwhile, in case of circulating the heat transport medium using a pump, the generated energy has to be consumed partially to drive the pump, that is, the overall output of the generation system is degraded. Moreover, in case of converting the stored heat into electric energy, an additional thermoelectric converter is required. In addition, in case of using the stored heat as a heat source, additional equipments and a heat transport means are required. Thus, according to the above-listed related art, the system configurations are significantly complicated.

Otherwise, the solar cell can also be cooled by radiating the heat to the outside as taught by Japanese Patent Laid-Open No. 61-134553 and Japanese Patent Laid-Open No. 58-83168. However, both of a light receiving face and a radiation face have to face the sky. That is, orientations of those faces are contradictory to each other. Thus, problems still remain in those related arts, for example, the systems taught by those documents have to be downsized, and cooling efficiency thereof has to be improved.

### SUMMARY

The present invention has been conceived noting above-mentioned problems, and it is therefore an object of the present invention is to provide a concentrating photovoltaic generation system capable of generating electric power without degrading generation efficiency and without enlarging a size of the generation system.

In order to achieve the aforementioned objective, according to an exemplary embodiment of the present invention, a concentrating photovoltaic generation system is provided, comprising: a photovoltaic generator for converting solar light into electric power; a reflector panel for concentrating the solar light onto the photovoltaic generator; and a radiation cooling mechanism radiating heat to the air thereby storing cold energy, and cooling the photovoltaic generator by the stored cold energy.

The reflector panel comprises a reflecting surface for concentrating the solar light onto the photovoltaic generator. The aforementioned radiation cooling mechanism comprises a heat exchange mechanism contacted with the photovoltaic generator in a manner to exchange heat therebetween, a radiating mechanism radiating the heat therefrom to the air, and a heat transport means transporting the heat between the heat exchange mechanism and the radiating mechanism.

The radiating mechanism comprises a cold storage member for storing cold energy, and at least one radiation fin for radiating the heat transported thereto from the heat exchange mechanism.

The cold storage member is situated radially outside of the reflector panel. In other words, the reflector panel may be disposed between the photovoltaic generator and the cold storage member. The heat transporting means includes a thermosiphon and a heat pipe for transporting the heat between the cold storage member and the heat exchange mechanism.

The at least one radiation fin is situated on a radially outer surface of the cold storage member; and the at least one radiation fin and the cold storage member are connected to each other in a manner to transport a heat through a thermosiphon or a heat pipe.

The concentrating photovoltaic generation system further comprises: a cold storage material held in the cold storage member; at least one internal fin arranged in the cold storage member; and a thermosiphon or a heat pipe connecting the at least one radiation fin and the at least one internal fin in a heat transmittable manner.

The concentrating photovoltaic generation system further comprises: a plurality of pipes penetrating thorough the cold storage member while being contacted with the cold storage material; a first header connecting first end portions of the pipes with the heat transport means; and a second header connecting second end portions of the pipes with the heat transport means.

The aforementioned pipes penetrate through the at least one internal fin in a manner to exchange a heat therebetween.

The concentrating photovoltaic generation system further comprises a heat spreader plate, which is arranged in the cold storage member, for spreading the heat transmitted thereto from the heat exchange mechanism through the cold storage material.

The concentrating photovoltaic generation system further comprises: a thermosiphon loop or a heat pipe loop partially penetrating through the cold storage member and the remaining portion thereof is exposed to the air. The at least one radiation fin is attached to the portion of the thermosiphon loop or the heat pipe loop exposed to the air.

The cold storage member is situated above the photovoltaic generator at a position not to shield the photovoltaic generator from the solar light. In other words, there may be a first side of the photovoltaic generator that faces the cold storage portion and a second side of the photovoltaic generator that faces the reflector panel. The heat transport means includes a thermosiphon or a heat pipe for transporting a heat between the cold storage member and the heat exchange mechanism.

The cold storage member is situated radially outside of the reflector panel. The heat transport means comprises: a cyclic conduit connecting the heat exchange mechanism and the radiating mechanism, a heat transport medium flowing through the cyclic conduit, and a pump, which is arranged on the cyclic conduit to circulate the heat transport medium in the conduit.

The concentrating photovoltaic generation system further comprises: a cold storage material held in the cold storage member; a plurality of pipes penetrating thorough the cold storage member while being contacted with the cold storage material; a first header connecting first end portions of the pipes with the heat transport means; a second header connecting second end portions of the pipes with the heat transport means; a heat transport medium held in the pipes and in the headers. The heat transport means is adapted to circulate the heat transport medium through the cyclic conduit via one of the header, the pipes and the first and second headers.

The concentrating photovoltaic generation system further comprises at least one internal fin arranged in the cold storage member, and the pipes penetrate through the at least one internal fin while being contacted therewith to exchange the heat.

The radiation cooling mechanism comprises: a cold storage member situated in a position to be shielded from the solar light by the reflector panel; a radiation face radiating the heat therefrom toward the sky, which is formed on the cold storage member; a cyclic conduit for cooling the photovoltaic generator by circulating the heat transport medium between the cold storage member and the photovoltaic generator; and a displacing mechanism for relatively moving at least one of the reflector panel and the cold storage member thereby exposing the radiation face to the sky. In other words, the displacing mechanism may move one or both of the reflector panel and the cold storage member, such that in a first position, the cold storage member is blocked by the reflector panel when viewed from a predetermined direction (e.g. from the sky), and in a second position, the cold storage member is not blocked by the reflector panel when viewed from the predetermined position.

The reflector panel comprises a reflecting surface for concentrating the solar light onto the photovoltaic generator. The cold storage member is formed integrally with a radially outer face of the reflector panel, and the radiation face is formed on a radially outer face of the cold storage member.

The displacement mechanism includes a mechanism for moving the integrated reflector panel and cold storage member to a position where the reflecting surface is exposed to the sun, and to a position where the radiation face is exposed to the night sky. In other words, the displacement mechanism may move the reflector panel and the cold storage member into a first position in which the reflector panel is exposed to a predetermined direction (e.g. exposed to the sky) and into a second position in which the radiation face is exposed to the predetermined direction.

The concentrating photovoltaic generation system further comprises a heat-insulating layer interposed between the reflector panel and the cold storage member.

The heat-insulating layer includes an air layer and a vacuum layer.

The heat storage material includes a latent heat storage material for storing cold energy in the form of latent heat resulting from a phase change thereof.

The reflector panel includes a plurality of slats rotated individually with respect to a horizontal axis, and the displacement mechanism includes a mechanism for rotating the slats to be vertical thereby exposing the radiation face of the cold storage member to a predetermined direction (e.g. the sky).

The cold storage member is adaptable to have a first width that is narrower than a width of the reflector panel or a second width that is wider than the width of the reflector panel. In this way the displacement mechanism may includes a mechanism for changing the width of the cold storage member such that the cold storage member has the first width or the second width.

According to another aspect of the present invention, there is provided a concentrating photovoltaic generation system, comprising: a thermoelectric conversion element for converting heat of solar light into electric power; a heated portion contacted to the thermoelectric conversion element in a heat transmittable manner; a reflector panel for concentrating the solar light to the heated portion; and a radiation cooling mechanism radiating the heat to the air thereby storing cold energy, and cooling the thermoelectric conversion by the stored cold energy.

The reflector panel comprises a reflecting surface for concentrating the solar light onto the heated portion. The radiation cooling mechanism comprises: a heat exchange mechanism contacted with the thermoelectric conversion element in a manner to exchange heat therebetween; a radiating mechanism radiating the heat therefrom to the air; and a heat transport means transporting the heat between the heat exchange mechanism and the radiating mechanism.

The radiating mechanism comprises a cold storage member for storing cold energy therein, and at least one radiating fin for radiating the heat transported from the cold storage member to the air.

The cold storage member is situated radially outside of the reflector panel, and the at least one radiation fin is situated on a radially outer surface of the cold storage member.

The heat transport means includes a thermosiphon and/or a heat pipe for transporting the heat between the cold storage member and the heat exchange mechanism. The at least one radiation fin and the cold storage member are connected to each other in a manner to transport a heat through another thermosiphon or heat pipe.

As explained above, exemplary concentrating photovoltaic generation systems according to the present invention comprise a radiation cooling mechanism adapted to radiate the heat to the air thereby storing the cold energy, and to cool the photovoltaic generator by the stored cold energy. Therefore, according to exemplary embodiments of the present invention, the cold energy can be stored without requiring any specific power sources, and photoelectric conversion efficiency will not be degraded by the heat.

The radiation cooling mechanism may comprise the heat exchange mechanism contacted with the photovoltaic generator in a manner to exchange the heat therebetween, and the heat transport means for transporting the heat between the heat exchange mechanism and the radiating mechanism. That is, according to exemplary embodiments of the present invention, only the heat exchange mechanism is contacted with the photovoltaic generator to draw the heat from the photovoltaic generator, and the radiation cooling mechanism for radiating the heat from the photovoltaic generator is situated at a position not to disturb the photovoltaic generator to receive the solar light through the heat transport means.

Specifically, the radiating mechanism comprises the cold storage member for storing the cold energy, and the radiation fin for radiating the heat transported thereto from the cold storage member. Therefore, the cold energy can be stored in the cold storage member by the radiation fin, and the photovoltaic generator can be cooled by the cold energy stored in the cold storage member. For this reason, photoelectric conversion efficiency will not be degraded by the heat.

Since the cold storage member is situated radially outside of the reflector panel, the heat can be transported from the photovoltaic generator to the cold storage member through the heat exchange mechanism by heat transport means such as the thermosiphon or heat pipe. Therefore, the photovoltaic generator can be cooled by the cold energy stored in the cold storage member, and the photoelectric conversion efficiency will not be degraded by the heat.

Since the cold storage member is situated radially outside of the reflector panel, the cold storage member will not be exposed to the solar light directly. Therefore, the cold storage member will not be heated by the solar light.

As described, the at least one radiation fin is arranged on the cold storage member, and the cold storage member and the at least one radiation fin are connected by the thermosiphon or heat pipe in a heat transmittable manner. Therefore, cold energy can be stored in the cold storage member by the at least one radiation fin.

The cold storage material and the at least one internal fin are held in the cold storage member, and the at least one internal fin and the at least one radiation fin are connected by the thermosiphon or heat pipe in a heat transmittable manner. Therefore, the heat transmitted to the cold storage material can be transmitted to the at least one internal fin, and then transmitted to the at least one radiation fin through the thermosiphon or heat pipe to be radiated to the air. Thus, the heat will not remain in the cold storage member so that the cold energy can be stored therein.

In addition to above, the heat spreader plate is arranged in the cold storage member. Therefore, the heat removed from the photovoltaic generator by the heat exchange mechanism and transported to the heat spreader plate is allowed to spread in the cold storage material entirely. For this reason, the heat transported to the cold storage member will not remain in the cold storage member, and the photovoltaic generator can be cooled efficiently by the cold energy stored in the cold storage member.

As described, the heat transport means comprises: the cyclic conduit connecting the heat exchange mechanism and the radiating mechanism; the heat transport medium flowing through the cyclic conduit; and the pump for circulating the heat transport medium. Therefore, the photovoltaic generator can be cooled in accordance with the temperature of the heat exchange mechanism by controlling an amount of the heat transport medium flowing through the cyclic conduit. Moreover, since the heat transport medium is circulated by the pump, flexibility of arrangement and design of the radiating mechanism can be widened.

As also described, the concentrating photovoltaic generation system according to exemplary embodiments of the present invention further comprises: the cold storage material held in the cold storage member; the plurality of pipes penetrating thorough the cold storage member while being contacted with the cold storage material; and the first and the second headers connecting the pipes with the heat transport means. The heat transport medium is circulated in the heat transport means via the heat exchange mechanism, one of the headers, the pipes and the other header. Thus, the heat removed from the photovoltaic generator by the heat exchange mechanism is transported to the cold storage member by the heat transport means.

Since the plurality of pipes penetrate through the at least one inner fin arranged in the cold storage member, the heat transported through the heat transport medium is allowed to spread entirely in the cold storage material.

As also explained, the concentrating photovoltaic generation system according to exemplary embodiments of the present invention further comprises a thermosiphon loop or a heat pipe loop partially penetrating through the cold storage member and the remaining portion thereof is exposed to the air, and the at least one radiation fin is attached to the portion of the thermosiphon loop or the heat pipe loop exposed to the air. Therefore, the heat transported to the cold storage material is transmitted to the thermosiphon loop or the heat pipe loop, and then radiated to the air from the at least one radiation fin exposed to the air. Moreover, since the heat is radiated by the thermosiphon loop or the heat pipe loop, the heat of the air will not be transmitted to the cold storage material.

According to exemplary embodiments of the concentrating photovoltaic generation system of the present invention, the solar light is concentrated to the photovoltaic generator by the reflector panel so that the solar energy is converted into the electric energy to generate electricity. In this situation, the photovoltaic generator is heated by the concentrated solar light. However, the heat transport medium is circulated between the cold storage member and the photovoltaic generator. Therefore, the heat is drawn from the photovoltaic generator and transported to the cold storage member. For this reason, generation efficiency of the photovoltaic generator can be kept without raising the temperature thereof. The heat is gradually stored in the cold storage member as a result of thus cooling the photovoltaic generator. However, in the nighttime, the cold storage member is moved relatively with respect to the reflector panel to expose the radiation face thereof. Therefore, the heat is radiated from the radiation face of the cold storage member and the cold storage material in the cold storage member is thereby cooled. The photovoltaic generator is cooled by the cold storage material thus cooled when performing solar generation. Therefore, generation efficiency of the photovoltaic generator can be kept in. In addition, the electric energy will not be consumed to cool the photovoltaic generator. Therefore, generated electric power can be outputted entirely.

According to exemplary embodiments of the present invention, moreover, the concentrating photovoltaic generation system can be structurally simplified by integrating the reflector panel and the cold storage member, and the radiative cooling can be performed easily by the cold storage member.

In this case, thermal efficiency can be improved by providing the heat-insulating layer between the reflector panel and the cold storage member.

According to exemplary embodiments of the present invention, still moreover, the cold storage member can be shielded from the solar light by the reflector panel. Therefore, the cold storage member will not be heated even in case of performing the solar generation, and the cold storage member is allowed to store the cold energy efficiently in the nighttime by radiating the heat therefrom.

Further, the latent heat storage material storing cold energy in the form of latent heat resulting from a phase change thereof is used as the cold storage material and held in the cold storage member. Therefore, a storage amount of the cold energy per unit volume can be increased so that the cold storage member can be downsized.

Furthermore, according to exemplary embodiments of the present invention, the solar light is concentrated into the photovoltaic generator by the reflector panel to convert the solar energy into the thermal energy thereby generating the electric energy. As described, the heated portion is contacted with one of the faces of the thermoelectric conversion element, and the radiation cooling mechanism is contacted to of the face of the thermoelectric conversion element. Therefore, in this situation, one of the faces of the thermoelectric conversion element is heated by the heated portion to which the solar light is concentrated, and other face of the thermoelectric conversion element is cooled by the radiation cooling mechanism. As a result, a temperature difference is created in the thermoelectric conversion element so that the electric energy can be generated efficiently. Although the heat is stored in the cold storage member during the cooling of the thermoelectric conversion element, the heat of the cold storage member is radiated to the air, and the cold storage member is thereby cooled. When performing the solar generation, the thermoelectric conversion element is cooled by the cold storage member thus cooled. Therefore, the generation efficiency of the thermoelectric conversion element can be kept preferably. In addition, the electric energy will not be consumed to cool the photovoltaic generator. Therefore, generated electric power can be outputted entirely.

### BRIEF DESCRIPTION OF THE DRAWINGS

These and other features, aspects, and advantages of exemplary embodiments of the present invention will become better understood with reference to the following description and accompanying drawings, which should not be read to limit the invention in any way, in which:

FIG. 1 is a conceptual diagram schematically showing an exemplary structure of the concentrating photovoltaic generation system according to the present invention;

FIG. 2 is a conceptual diagram schematically showing another exemplary structure of the concentrating photovoltaic generation system according to the present invention;

FIG. 3 is a view schematically showing an example of concentrating photovoltaic generation system according to the present invention;

FIG. 4 is a view schematically showing another example of concentrating photovoltaic generation system according to the present invention;

FIG. 5 is a view showing the configuration of the example shown in FIG. 4 in more detail;

FIG. 6 is a view schematically showing still another example of concentrating photovoltaic generation system according to the present invention;

FIG. 7 is a view schematically showing still another example of concentrating photovoltaic generation system according to the present invention;

FIG. 8 is a view schematically showing still another example of concentrating photovoltaic generation system according to the present invention;

FIG. 9 is a view schematically showing a internal structure of the example shown in FIG. 8;

FIG. 10 is a conceptual view schematically showing a connection between the photovoltaic generator and the cold storage member;

FIG. 11 is a view schematically showing an example of the concentrating photovoltaic generation system of the present invention in which the heat transport medium is circulated by the pump;

FIG. 12 is a conceptual view schematically showing a c connection between the photovoltaic generator and the cold storage member;

FIG. 13 is a view schematically showing another example of the concentrating photovoltaic generation system of the present invention in which the heat transport medium is circulated by the pump;

FIG. 14 is a view schematically showing an exemplary solar electric power station using the concentrating photovoltaic generation system of the present invention;

FIG. 15 is a side view schematically showing an example of the concentrating photovoltaic generation system of the present invention performing solar generation;

FIG. 16 is a cross-sectional view schematically showing a portion of the exemplary reflector panel and the exemplary cold storage member;

FIG. 17 is a side view schematically showing an exemplary radiation face facing the sky;

FIG. 18 is a side view schematically showing another example of the concentrating photovoltaic generation system of the present invention performing solar generation;

FIG. 19 is a side view schematically showing an exemplary reflector panel displaced from the position above the radiation face;

FIG. 20 is a side view schematically showing the displaced reflector panel of still another example of the concentrating photovoltaic generation system;

FIG. 21 is a side view schematically showing an alternative of the reflector panel opened to expose the radiation face to the sky;

FIG. 22 is a side view schematically showing an alternative of the cold storage member widened to expose the radiation face partially;

FIG. 23 is a side view schematically showing another alternative of the cold storage member made of flexible material and rolled to be shielded by the reflector panel;

FIG. 24 is a side view schematically showing the unrolled cold storage member shown in FIG. 23;

FIG. 25 is a side view schematically showing still another alternative of the cold storage member made of flexible material and rolled to be shielded by the reflector panel; and

FIG. 26 is a side view schematically showing the unrolled cold storage member shown in FIG. 25.

### DETAILED DESCRIPTION

Hereinafter, exemplary embodiments of the concentrating photovoltaic generation system according to the present invention will be explained with reference to the accompanying drawings. According to the present invention, the concentrating photovoltaic generation systems are adapted to convert the solar light into heat, more specifically, to perform solar generation efficiently by concentrating the solar light to the photovoltaic generator.

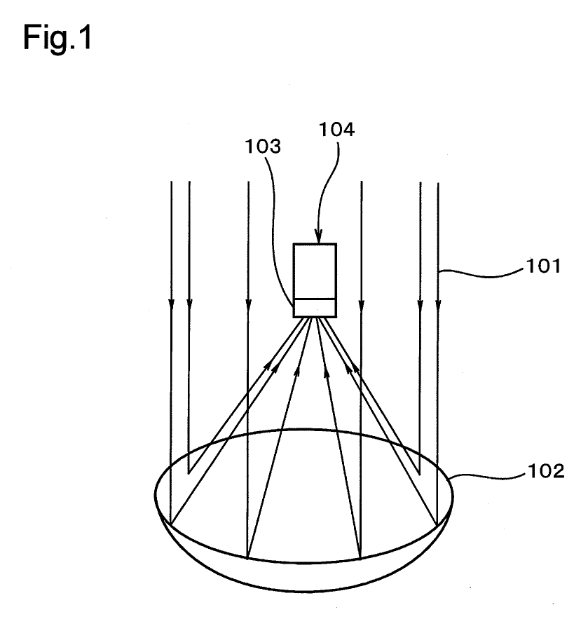

FIG. 1 shows a fundamental structure of an exemplary concentrating photovoltaic generation system. As shown in FIG. 1, the system is provided with a reflector panel 102 for reflecting solar light 101, and a photovoltaic generator 103 for converting the solar light 101 into electric power is arranged at a focal point of the reflector panel 102. For example, a photoelectric conversion element such as an amorphous solar cell can be used as the photovoltaic generator 103. Solar light 101 may be concentrated to the photovoltaic generator 103 not only by reflecting but also refracting the solar light. In case of concentrating the solar light 101 to the photovoltaic generator by reflecting the solar light 101, a plurality of flat mirrors, or a cylindrical mirror reflector, may also be employed instead of the reflector panel 102. In case of concentrating the solar light 101 to the photovoltaic generator by refracting the solar light 101, a Fresnel lens or the like may be used. Therefore, the generation system is allowed to generate electric power efficiently by concentrating the solar light 101 to the photovoltaic generator 103.

A positional relationship between the reflector panel 102 and the photovoltaic generator 103 may be fixed. Thus, the reflector panel 102 and the photovoltaic generator 103 may be supported by a frame not shown. Specifically, a conventional photoelectric conversion element such as an amorphous solar cell adapted to convert the light into electricity can be used as the photovoltaic generator 103. In the example shown in FIG. 1, a bottom face of the photovoltaic generator 103 serves as a light receiving face onto which the reflected light is concentrated, and a radiation cooling mechanism 104 is contacted on the face opposite to the light receiving surface in a manner to cool the photovoltaic generator 103 by drawing the heat therefrom.

In addition, a thermoelectric conversion element adapted to convert the heat into electricity can also be used instead of the photovoltaic generator 103. In this case, a heated portion is arranged at the focal point of the reflector panel 102, and the solar light is concentrated to an outer face thereof functioning as a light receiving face to heat the heated portion. The thermoelectric conversion element is arranged on a face of the heated portion opposite to the light receiving face (i.e., a heated face) in a manner to transmit the heat therebetween. In order to cool the thermoelectric conversion element, the radiation cooling mechanism 104 is contacted to a face of the thermoelectric conversion element opposite to the face to which the heated portion is contacted. Thus, a temperature difference is created in the thermoelectric conversion element.

As in the case of using the photoelectric conversion element, the thermoelectric conversion element is arranged at a focal point of the reflector panel 102 to heat one of the faces thereof, that is, to a light receiving face thereof by concentrate the solar light 101 thereto. Also, the radiation cooling mechanism 104 is contacted on the face the thermoelectric conversion element opposite to the light receiving face in a manner to draw the heat therefrom. The contacting face of the thermoelectric conversion element is thus cooled to create a temperature difference therein.

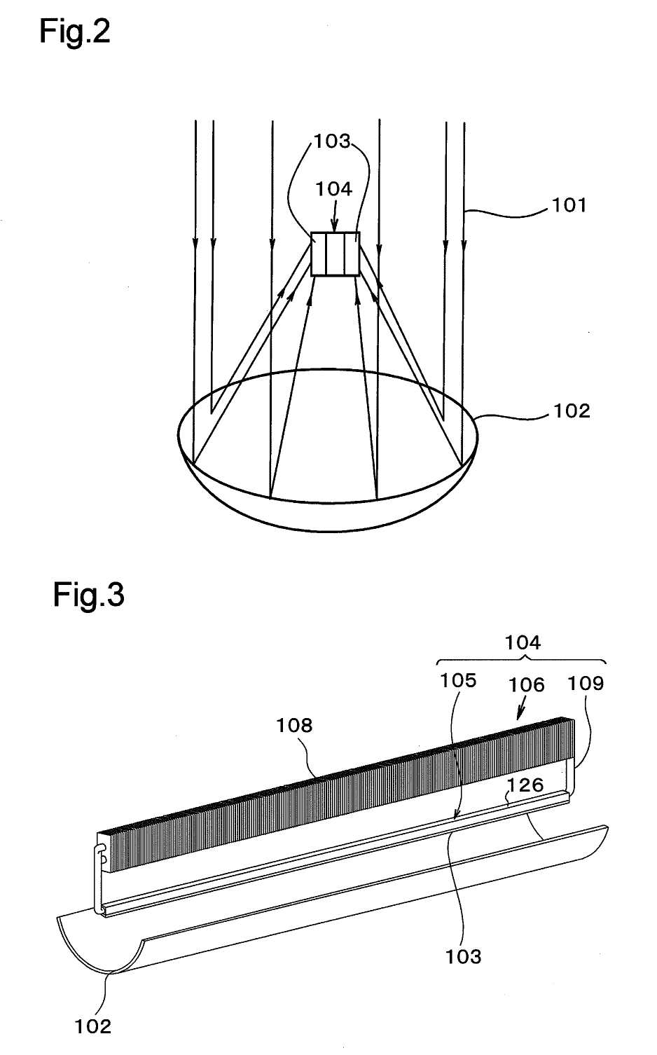

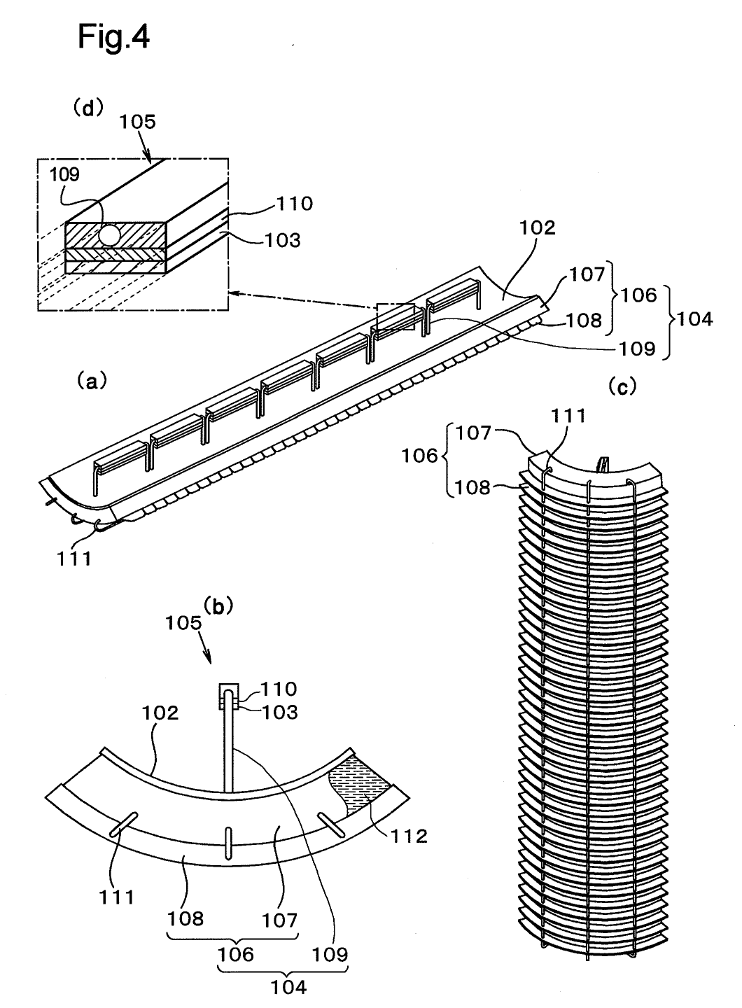

Alternatively, as schematically shown in FIG. 2, the radiation cooling mechanism 104 may also be situated between a pair of photovoltaic generators 103. The radiation cooling mechanism 104 comprises a heat exchange mechanism 105 (shown in FIG. 3) receiving the heat generated in the photovoltaic generator 103, a heat transport means for transporting the heat, and a radiating mechanism 106 (shown in FIG. 3). The radiating portion comprises a cold storage member 107 (shown in FIG. 4) for storing cold energy, and radiation fins 108 (shown in FIG. 4) for radiating the heat transmitted thereto from the storage member 107 to the air.

Basically, all of the examples of the concentrating photovoltaic generation system according to this exemplary embodiment comprise the fundamental structure shown in FIG. 1 or 2. Specifically, the concentrating photovoltaic generation system shown in FIG. 3 comprises: a photovoltaic generator 103 arranged at a focal point of the reflector panel 102 to which solar light 101 reflected by the reflector panel 102 is concentrated; a plurality of radiation fins 108 juxtaposed to each other to form a fin array; and a looped heat transport means 109 extending along the photovoltaic generator 103 and penetrating through the array of the fins 108.

Specifically, the heat transport means 109 may be a thermosiphon loop and/or a heat pipe loop made of copper or copper alloy, comprising: a hollow container; and a volatile working fluid encapsulated in the container. A non-condensable gas may be evacuated from the container to reduce an inner pressure of the container. A portion of the heat transport means 109 extending along the photovoltaic generator 103 while being contacted therewith functions as an evaporating portion, that is, functions as a heat exchange mechanism 105. On the other hand, a portion of the heat transport means 109 penetrating through the array of the fins 108 while being contacted therewith functions as a condensing portion. That is, the condensing portion of the heat transport means 109 and the fins 108 constitute a radiating mechanism 106. Basically, water and alcohol are the most common fluids to be used as the working fluid taking into consideration the freezing points and the boiling points thereof.

As described, the photovoltaic generator 103 receives the solar light 101 reflected by the reflector panel 102. The solar light 101 concentrated by the reflector panel 102 is partially converted into heat without being converted into electricity. Therefore, the photovoltaic generator 103 is heated by this heat. The heat generated in the photovoltaic generator 103 is transmitted to the evaporating portion of the heat transport means 109 functioning as the heat exchange mechanism 105. The working fluid in the heat exchange mechanism 105 is vaporized by the heat transmitted to the heat exchange mechanism 105. As a result, the heat is drawn from the photovoltaic generator 103 by the working fluid. The vaporized working fluid then migrates to the condensing portion, that is, to the radiating mechanism 106, and dissipates to the air thorough the radiation fins 108. In this situation, the heat of the working fluid vapor is drawn by the fins 108 and the working fluid in the vapor phase is thereby condensed. In order to expedite convection of the working fluid thus condensed in the condensing portion (i.e., by the fins 108) toward the evaporating portion (i.e., to the heat exchange mechanism 105) by a capillary action, a wick or a porous material may be arranged in the container of the heat transport means 109.

According to the concentrating photovoltaic generation system, the photovoltaic generator 103 is thus cooled by a working fluid circulating in the heat transport means 109 while changing the phase thereof repeatedly. Therefore, an efficiency of photoelectric conversion of the photovoltaic generator 103 will not be degraded by the heat. For this reason, the electromotive force can be stabilized so that the photovoltaic generation can be carried out stably. Moreover, the photovoltaic generator 103 can be cooled without requiring any special power source. This means that the generated electric power will not be consumed to operate the photovoltaic generation system itself. That is, the generated electric power can be outputted entirely.

An alternative of the photovoltaic generation system is shown in FIG. 4. Specifically, FIG. 4 (a) is a perspective view, FIG. 4 (b) is a side view, FIG. 4 (c) is a back view, and FIG. 4 (d) is a partial enlarged view. As shown in FIG. 4 (b), the photovoltaic generator 103 is situated at the focal point of the reflector panel 102. According to the example shown in FIG. 4, a heat spreader plate 110 is attached to an upper face of the photovoltaic generator 103 in a manner to transmit the heat therebetween. Further, the heat transport means 109 extends on an upper face of the heat spreader plate 110 to transport the heat transmitted thereto from the heat spreader plate 110. Meanwhile, a cold storage member 107 holding a cold storage material 112 therein is formed radially outside of the reflector panel 102. Here, the cold storage member 107 may also be formed integrally with the reflector panel 102. According to this example, a plurality of thermosiphon loops or heat pipe loops are used as the heat transport means 109. As in the example shown in FIG. 3, each of the heat transport means 109 may be made of copper or copper alloy, and holds the working fluid and the wick or porous material in its container.

As shown in FIGS. 4 (a) and 4 (b), the heat transport means 109 connects the heat spreader plate 110 and the cold storage member 107. Therefore, according to the example shown in FIG. 4, a heat receiving portion or an evaporating portion of the heat transport means 109, that is, the portion of the heat transport means 109 contacted with the photovoltaic generator 103 through the heat spreader plate 110 in a heat transmittable manner, and the heat spreader plate 110 constitute the heat exchange mechanism 105. On the other hand, a portion of the heat transport means 109 buried in the cold storage member 107 functions as a condensing portion of the heat transport means 109. In addition, according to the example shown in FIG. 4, the radiation fins 108 are arranged radially outside of the cold storage member 107, and the radiation fins 108 and the cold storage member 107 are connected to each other through a heat pipe loop 111. Therefore, the heat transmitted to the cold storage member 107 from the heat transport means 109 is then transmitted to the radiation fins 108 and dissipated to the air therefrom. Accordingly, the cold storage member 107 and the radiation fins 108 constitute the radiating mechanism 106, and the cold storage member 107, the radiation fins 108 and the heat transport means 109 constitute the radiation cooling mechanism 109.

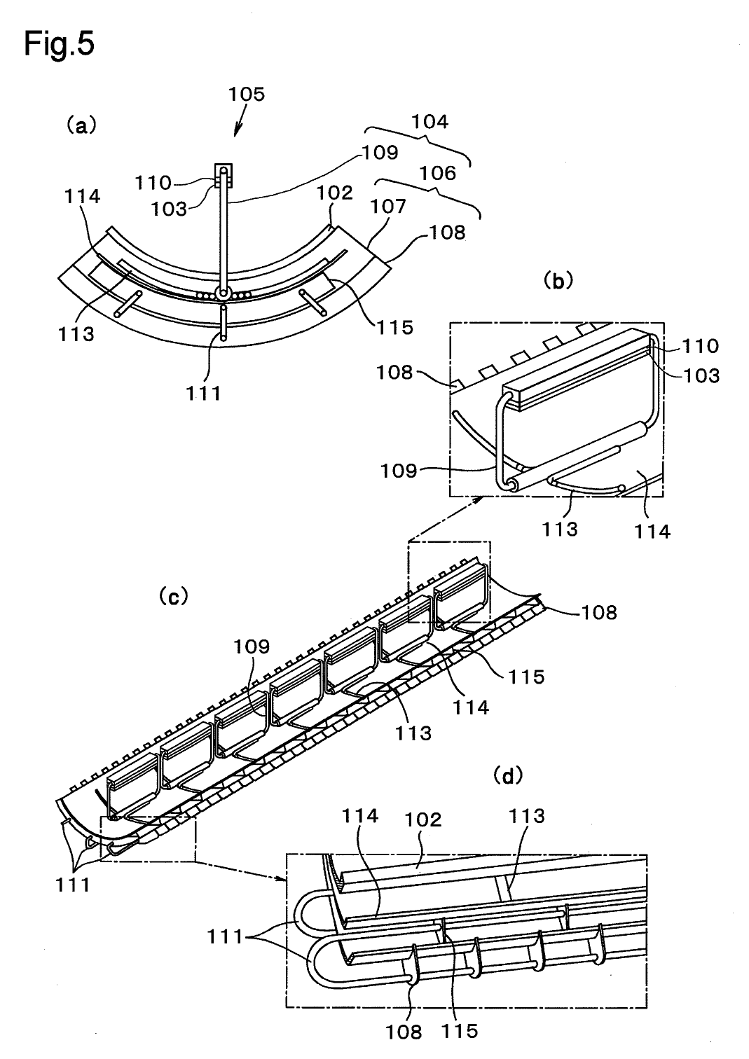

The photovoltaic generation system shown in FIG. 4 is depicted in more detail in FIG. 5. Specifically, FIG. 5 (a) is a view schematically showing an internal structure of the generation system, FIG. 5 (b) is a partial enlarged view of the internal structure, FIG. 5 (c) is a perspective view of the generation system, and FIG. 5 (d) is a sectional view of the cold storage member 107. As described, the cold storage material 112 is held in the cold storage member 107. For example, a conventional latent heat storage material such as water or ethylene glycol can be used as the cold storage material 112. As shown in FIG. 5 (a), the cold storage member 107 comprises a plurality of L-shaped heat pipes 113. The heat pipe 113 is contacted with the condensing portion of the heat transport means 109 and transports the heat toward the lateral end of the reflector panel 102. Therefore, the heat transmitted to the cold storage member 107 can be spread homogeneously throughout the cold storage material 112. The cold storage member 107 further comprises an internal heat spreader plate 114 being contacted with the condensing portion of the heat transport means 109 in a heat transmittable manner to spread the heat through the cold storage material 112, and a plurality of internal fins 115 juxtaposed to each other in the cold storage member 107 while being contacted with the internal heat spreader plate 114 in a heat transmittable manner. As also described, the radiation fins 108 are erected on the radially outer surface of the cold storage member 107. The internal fins 115 and the radiation fins 108 are communicated with each other through the heat pipe loop 111. Therefore, the heat is transmitted from the cold storage member 107 to the radiation fins 108 through the heat pipe loop 111, and dissipated to the air from the radiation fins 108.

The temperature of the photovoltaic generator 103 is raised as a result of receiving the solar light 101 reflected by the reflector panel 102. The heat of the photovoltaic generator 103 is transmitted to the heat exchange mechanism 105 being contacted thereto, that is, to the heat spreader plate 110 and to the evaporating portion of the heat transport means 109. As a result, the working fluid in the evaporating portion is vaporized so that the heat is drawn from the photovoltaic generator 103 by the latent heat of the vaporized working fluid. Then, the vaporized working fluid migrates to the condensing portion of the heat transport means 109 buried in the cold storage material 112. The heat transmitted to the condensing portion by the vaporized working fluid is then transmitted to the L-shaped heat pipe 113 and to the internal heat spreader plate 114. Consequently, the heat of the vaporized working fluid is drawn by the heat pipe 113 and the internal heat spreader plate 114, and the working fluid is thereby condensed. The heat transmitted to the internal heat spreader plate 114 is transmitted to the internal fins 115, and then transmitted to the radiation fins 108 through the heat pipe loop 111. As a result, the heat is radiated from the fins 108 to the air. Thus, the heat of the photovoltaic generator 103 is radiated to the air by the repetition of circulation of the working fluid.

Since the photovoltaic generator 103 is thus cooled, an efficiency of the photoelectric conversion of the photovoltaic generator 103 will not be degraded by the heat. Therefore, the electromotive force of the photovoltaic generation can be stabilized. Moreover, the photovoltaic generator 103 can be cooled without requiring any special power source. This means that the generated electric power will not be consumed to operate the photovoltaic generation system itself. That is, the generated electric power can be outputted entirely. In addition, the radiation cooling mechanism 104 is capable of drawing the heat not only from the photovoltaic generator 103 but also from the cold storage material 112 by the radiation fins 108, in case the external temperature is lower than the temperature of the cold storage material 112 in the cold storage member 107. Specifically, in case the external temperature drops in the nighttime, the heat of the cold storage material 112 is radiated through the radiation fins 108 and the cold storage material 112 is thereby cooled. The cold energy thus stored is utilized to cool the photovoltaic generator 103 performing the photovoltaic generation in the daytime.

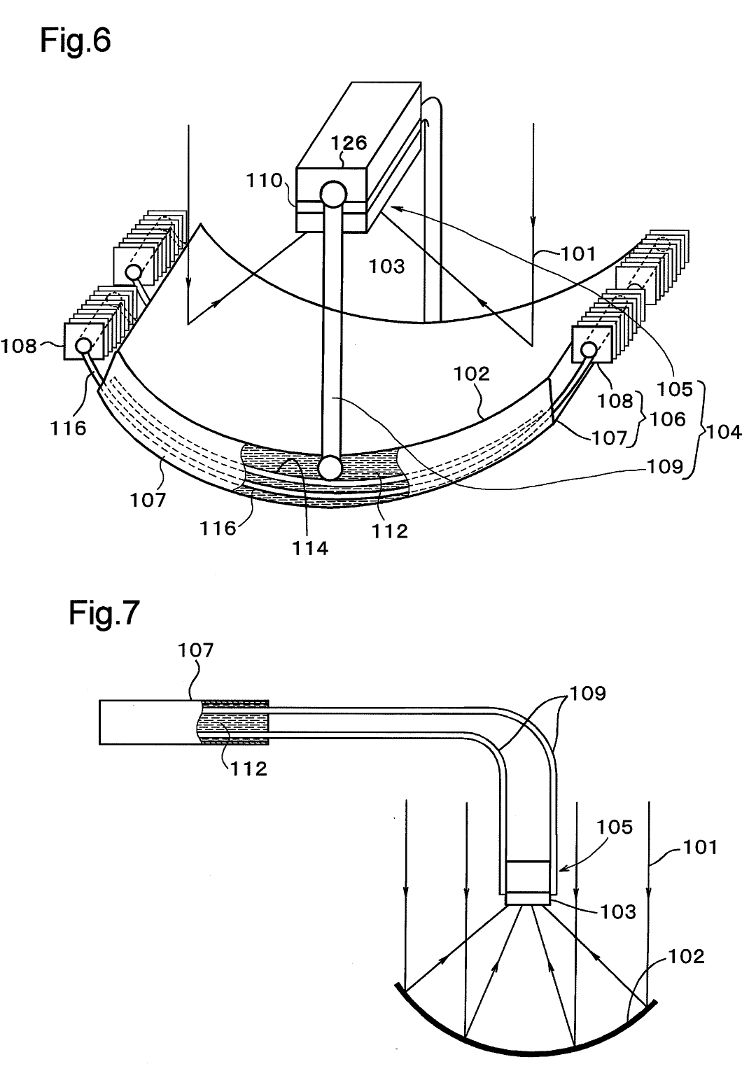

Another example of the concentrating photovoltaic generation system according to the present invention is shown in FIG. 6. As shown in FIG. 6, the photovoltaic generator 103 is arranged at the focal point of the reflector panel 102. In this example, the heat spreader plate 110 is formed on the face of the photovoltaic generator 103 opposite to the face facing to the reflector panel 102. As in the above-explained examples, the heat transport means 109 may be a heat pipe loop or a thermosiphon loop made of copper or copper alloy, and the heat transport means 109 holds a working fluid and a wick therein. As shown in FIG. 6, one of the sides of the heat transport means 109 extends on the heat spreader plate 110 while being contacted therewith. That is, the portion of the heat transport means 109 contacted with the heat spreader plate 110 receives the heat from the heat spreader plate 110 and functions as the evaporating portion. Thus, the heat spreader plate 110 and the evaporating portion of the heat transport means 109 constitute the heat exchange mechanism 105 of this example.

The cold storage member 107 is formed radially outside of the reflector panel 102. Here, the cold storage member 107 may be a separate thin trough-shaped container, but may also be formed integrally with the reflector panel 102. The cold storage material 112 for storing the cold energy is held in the cold storage member 107. As described, a latent heat storage material such as water or ethylene glycol can be used as the cold storage material 112. In order to spread the heat all over the cold storage material 112 homogeneously, the internal heat spreader plate 114 is provided in the cold storage member 107 while being contacted with the condensing portion of the heat transport means 109, that is, with the portion of heat transport means 109 in the cold storage member partially or entirely. In addition, the internal heat spreader plate 114 is curved in accordance with the curvature of the reflector panel 102. Further, one or more heat pipe loops 116 extend transversely across the cold storage member 117, and a plurality of the radiating fins 108 are juxtaposed on the transverse end of the heat pipe loops 116, that is, on the portion of the heat pipe loops 116 outside of the transverse end of the reflector panel 102. Here, the heat pipe loops 116 also contains the working fluid and a wick according to need, and also curved in accordance with the curvature of the reflector panel 102.

The solar light 101 reflected by the reflector panel 102 is concentrated to the photovoltaic generator 103 and the temperature of the photovoltaic generator 103 is thereby raised. The heat generated in the photovoltaic generator 103 is transmitted to the heat spreader plate 110, and then transmitted to the evaporating portion of the heat transport means 109. When the heat is transmitted to the evaporating portion of the heat transport means 109, the working fluid held therein is evaporated by the heat. The vaporized working fluid migrates in the heat transport means 109 to the condensing portion thereof, that is, to the portion buried in cold storage member 107. In the condensing portion, the heat is drawn from the vaporized working fluid by the cold storage material 112 and the internal heat spreader plate 114. As a result, the working fluid is condensed in the condensing portion. The heat transmitted to the internal heat spreader plate 114 is then transmitted to the plurality of the heat pipe loops 116 being contacted therewith. The heat transmitted to the heat pipe loops 116 is then transmitted to the radiation fins 108 juxtaposed on the outermost sides of the heat pipe loops 116, and radiated to the air from the fins 108. Thus, the heat of the photovoltaic generator 103 is radiated to the air by the repetition of circulation of the working fluid.

Accordingly, the cold storage member 107 and the plurality of radiation fins 108 constitute the radiating mechanism 106 of this example. On the other hand, the heat exchange mechanism 105, the radiating mechanism 106 and the heat transport means 109 constitute the radiation cooling mechanism 104 of this example.

Since the photovoltaic generator 103 is thus cooled, an efficiency of the photoelectric conversion of the photovoltaic generator 103 will not be degraded by the heat. Therefore, the electromotive force of the photovoltaic generation can be stabilized. Moreover, the photovoltaic generator 103 can be cooled without requiring any special power source. This means that the generated electric power will not be consumed to operate cooling system of the photovoltaic generation system. That is, the generated electric power can be outputted entirely. In addition, the radiation cooling mechanism 104 is capable of drawing the heat not only from the photovoltaic generator 103 but also from the cold storage material 112 by the radiation fins 108, in case the external temperature is lower than the temperature of the cold storage material 112 in the cold storage member 107. Specifically, in case the external temperature drops in the nighttime, the heat of the cold storage material 112 is radiated through the radiation fins 108 and the cold storage material 112 is thereby cooled. The cold energy thus stored is utilized to cool the photovoltaic generator 103 performing the photovoltaic generation in the daytime.

An example of situating the cold storage member 107 at a position where the cold storage member 107 does not shield the photovoltaic generator 103 from the solar light is schematically shown in FIG. 7. As shown in FIG. 7, the photovoltaic generator 103 is arranged at the focal point of the reflector panel 102. In this example, the cold storage member 107 is situated away from the photovoltaic generator 103. The photovoltaic generator 103 and the cold storage member 107 are connected by the heat transport means 109 in a manner to exchange the heat therebetween. Accordingly, in this example, a portion of the heat transport means 109 contacted with the photovoltaic generator 103 functions as the evaporating portion, i.e., as the heat exchange mechanism 105, and a portion of the heat transport means 109 contacted with the cold storage member 107 functions as the condensing portion. In FIG. 7, the reference numeral 101 represents the solar light.

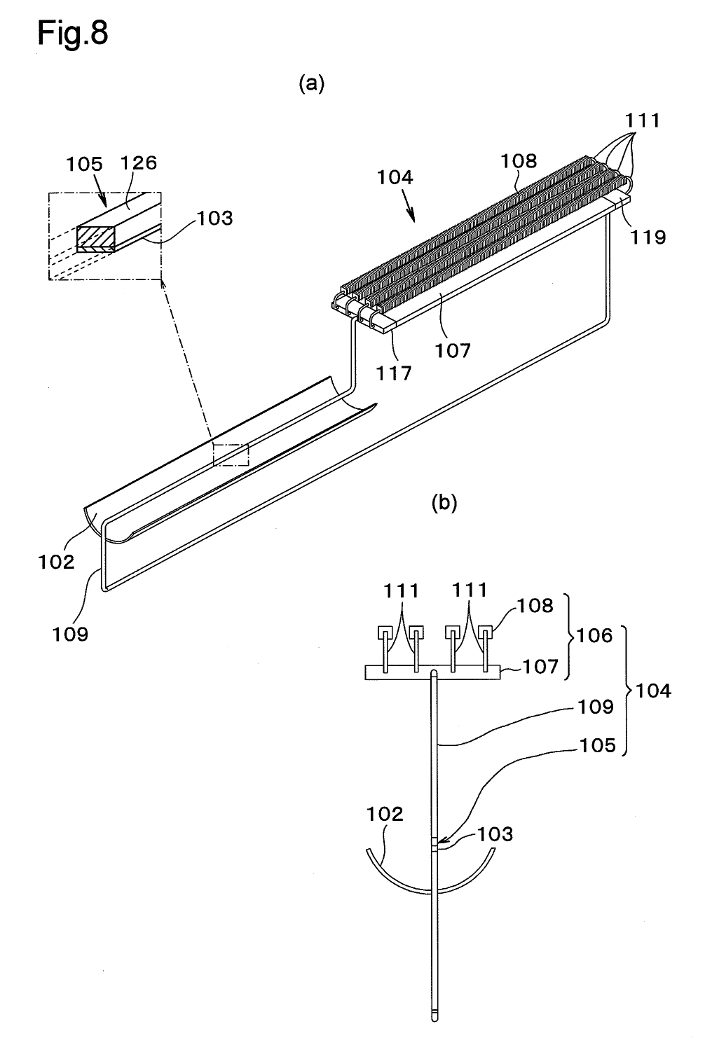

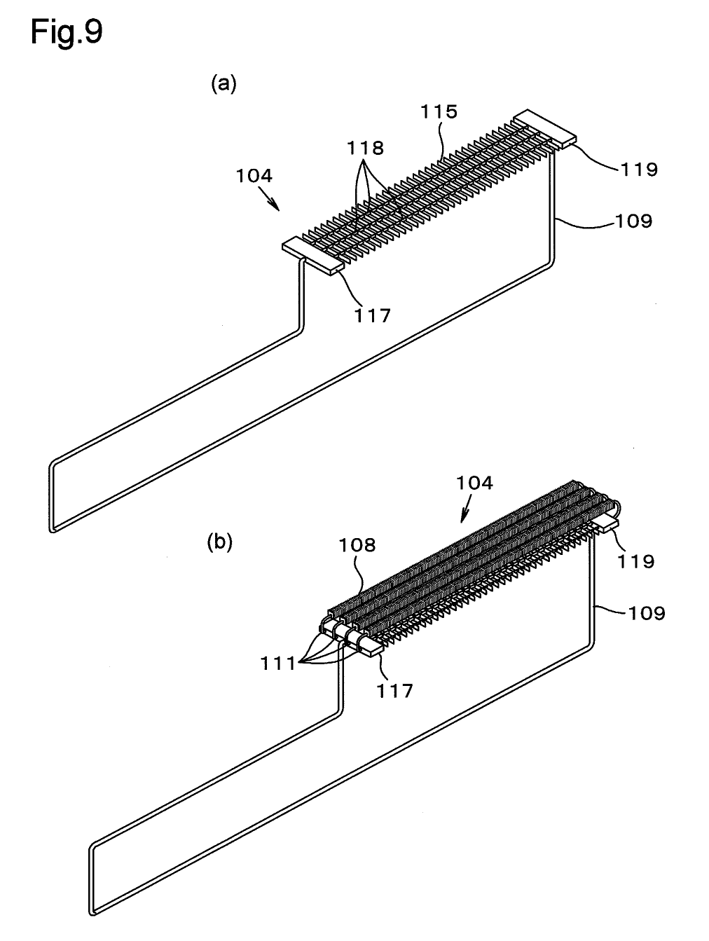

The example shown in FIG. 7 is depicted in more detail in FIGS. 8 and 9. Specifically, FIG. 8 (a) is a schematic view, and FIG. 8 (b) is a side view of the system shown in FIG. 7. FIG. 9 (a) is a perspective view showing an internal structure of the cooling mechanism, and FIG. 9 (b) is a perspective view showing an internal structure of the radiating mechanism. As described, the photovoltaic generator 103 is arranged at the focal point of the reflector panel 102. As in the above-explained examples, the heat transport means 109 may be a heat pipe loop or a thermosiphon loop made of copper or copper alloy, and the heat transport means 109 holds the working fluid in its container, and a wick is arranged therein according to need.

As shown in FIG. 8 (a), the cold storage member 107 is situated on a position where the cold storage member 107 does not shield the photovoltaic generator 103 from the solar light 101 reflected by the reflector panel 102, that is, situated above an extension of the reflector panel 102. Therefore, the heat transport means 109 is bent upwardly at a vicinity of end portion of the reflector panel 102 of the cold storage member 107, and bent at a level of the cold storage member 107 to enter into the cold storage member 107.

As in the above-explained examples, the cold storage material 112 is held in the cold storage member 107. In addition, as shown in FIG. 9 (a), a plurality of internal fins 115 is juxtaposed to each other in the cold storage member 107. On the other hand, the heat transport means 109 entering into the cold storage member 107 is divided into a plurality of pipes 118 by one of headers 117 and merged into the heat transport means 109 by the other header 117. Therefore, in the cold storage member 107, the pipes 118 penetrate the internal fins 115 in a manner to exchange the heat therebetween while being contacted with the cold storage material 112. Accordingly, the pies 118 function as the condensing portion of this example.

As shown in FIG. 9 (b), arrays of radiation fins 108 are arranged on an upper face of the cold storage member 107, and each array of the radiation fins 108 is communicated individually with the internal structure of the cold storage member 107 via a heat pipe loop 111. That is, in the cold storage member 107, the heat pipe loops 111 also penetrate the internal fins 115 in a manner to exchange the heat therebetween.

The solar light 101 reflected by the reflector panel 102 is concentrated to the photovoltaic generator 103 and the temperature of the photovoltaic generator 103 is thereby raised. The heat generated in the photovoltaic generator 103 is transmitted to the heat exchange mechanism 105, that is, to the evaporating portion of the heat transport means 109. When the heat is transmitted to the evaporating portion of the heat transport means 109, the working fluid held therein is evaporated by the heat, and the heat is drawn from the photovoltaic generator 103 by the latent heat of the vaporized working fluid. The vaporized working fluid migrates in the heat transport means 109 to the condensing portion thereof, that is, to the pipes 118 in cold storage member 107. In the condensing portion, the heat of the pipes 118 spreads all over the cold storage material 112 via the internal fins 115 being contacted with the pipes 118. In other words, the heat is drawn from the vaporized working fluid by the cold storage material 112. As a result, the working fluid is condensed in the condensing portion. The heat transmitted to the cold storage material 112 is then transmitted to the heat pipe loops 111 via the internal fins 115. The heat transmitted to the heat pipe loop 111 is transported to the radiation fins 108 juxtaposed on the upper face of the cold storage member 107 and radiated to the air from the fins 108. Thus, the heat of the photovoltaic generator 103 is radiated to the air by the repetition of circulation of the working fluid.

Accordingly, the cold storage member 107, the plurality of radiation fins 108 and the heat pipe loops 111 constitute the radiating mechanism 106 of this example. On the other hand, the heat exchange mechanism 105, the radiating mechanism 106 and the heat transport means 109 constitute the radiation cooling mechanism 104 of this example.

Since the photovoltaic generator 103 is thus cooled, an efficiency of the photoelectric conversion of the photovoltaic generator 103 will not be degraded by the heat. Therefore, the electromotive force of the photovoltaic generation can be stabilized. Moreover, the photovoltaic generator 103 can be cooled without requiring any special power source. This means that the generated electric power will not be consumed to operate the photovoltaic generation system itself. That is, the generated electric power can be outputted entirely. In addition, the radiation cooling mechanism 104 is capable of drawing the heat not only from the photovoltaic generator 103 but also from the cold storage material 112 by the radiation fins 108, in case the external temperature is lower than the temperature of the cold storage material 112 in the cold storage member 107. Specifically, in case the external temperature drops in the nighttime, the heat of the cold storage material 112 is radiated through the radiation fins 108 and the cold storage material 112 is thereby cooled. The cold energy thus stored is utilized to cool the photovoltaic generator 103 performing the photovoltaic generation in the daytime.

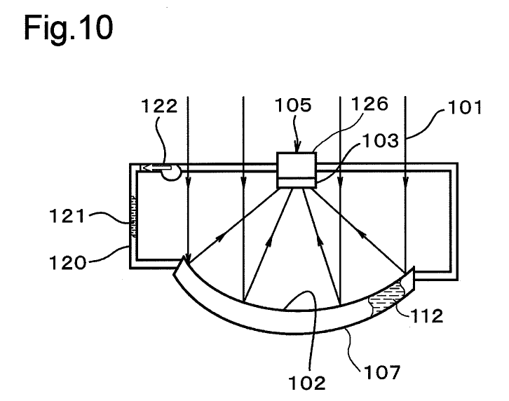

An example of cooling the photovoltaic generator 103 by circulating the cold storage material using a power source instead of using the heat pipe is schematically shown in FIG. 10. As shown in FIG. 10, the photovoltaic generator 103 is arranged at the focal point of the reflector panel 102. The cold storage member 107 holding the thermal storage material 112 therein is formed radially outside of the reflector panel 102, and the photovoltaic generator 103 and the cold storage member 107 are communicated with each other through a cyclic conduit 120. Specifically, the cyclic conduit 120 is formed to penetrate through a heat exchange mechanism 105, and both end thereof are connected individually to end portions of the reflector panel 102. A heat transport medium 121 is encapsulated in the cyclic conduit 120, and circulated therein via the cold storage member 107 by a pump 122. Here, the cold storage member 107 may be integrated with the reflector panel 102.

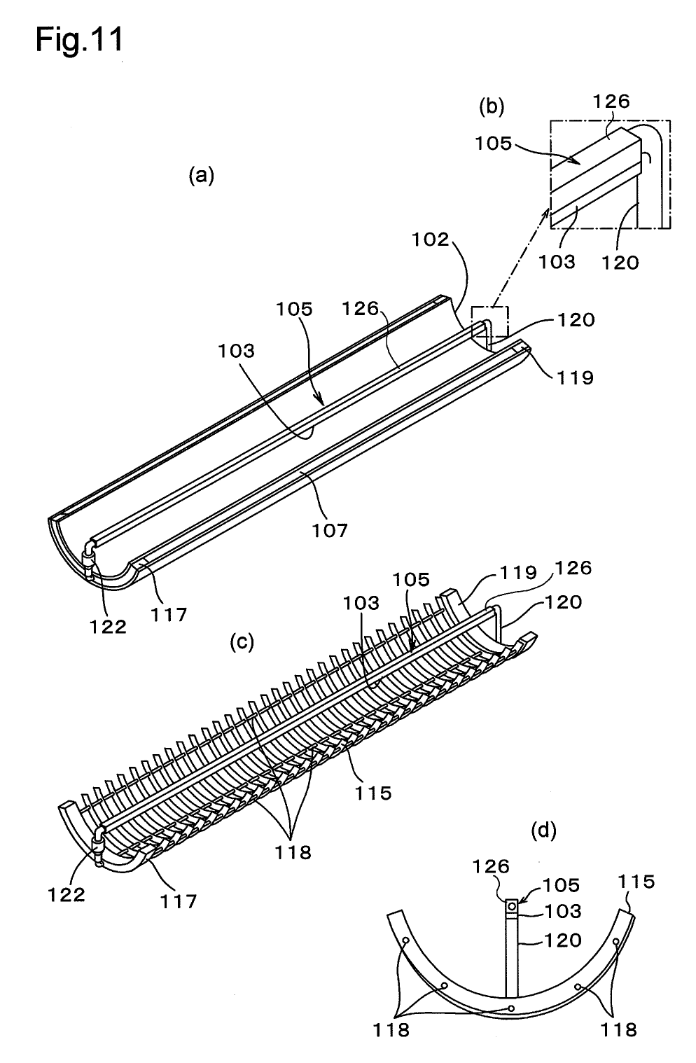

The example shown in FIG. 10 is depicted in more detail in FIG. 11. Specifically, FIG. 11 (a) is a schematic view, FIG. 11 (b) is an enlarged view showing the photovoltaic generator 103 and the heat exchange mechanism 105, FIG. 11 (c) is a perspective view showing an internal structure of the cold storage member 107, and FIG. 11 (d) is a sectional view of the cold storage member 107. As shown in FIG. 11 (a), the photovoltaic generator 103 is arranged at the focal point of the reflector panel 102. As described, the cold storage member 107 holding the cold storage material 112 is formed radially outside of the reflector panel 102, and both ends of the cold storage member 107 are connected to each other through the cyclic conduit 120. As also described, the heat transport medium 121 is encapsulated in the cyclic conduit 120. As shown in FIG. 11 (b), the photovoltaic generator 103 is situated underneath the cyclic conduit 120. That is, a portion of the cyclic conduit extending above the photovoltaic generator 103 while being contacted therewith in a heat transmittable manner functions as the heat exchange mechanism 105 of this example. Thus, the cold storage member 107 and the heat exchange mechanism 105 are connected to each other thorough the cyclic conduit 120 in a manner to transport the heat therebetween. In this example, the pump 122 for circulating the heat transport medium 121 is attached to the cyclic conduit 120 in the vicinity of one of the end portion of the cyclic conduit 120. The pump 122 is driven by electric energy generated by the photovoltaic generation.

In case both of the heat transport medium 121 circulating in the cyclic conduit 120 and the cold storage material 112 in the cold storage member 107 are water, any specific pipe is not required for letting through the heat transport medium 121 in the cold storage member 107. However, in case of using other material such as ethylene glycol as the cold storage material 112, an additional pipe may be arranged penetrating through the cold storage member 107 in order to transfer the heat to the cold storage member 107.

As shown in FIG. 11 (c), a plurality of inner fins 115 is juxtaposed to each other in the cold storage member 107. In case of using other material such as ethylene glycol as the cold storage material 112, as shown in FIGS. 11 (c) and (d), a plurality of pipes 118 are arranged in the cold storage member 107 while penetrating through the inner fins 115, and both ends of the pipes 118 are communicated individually with the cyclic conduit 120 at headers 117 and 119. Therefore, heat transport medium 121 is allowed to circulate in the cyclic conduit 120 thorough the pipes 118 while exchanging the heat with the cold storage material 112 in the cold storage member 107, without being mixed therewith.

The solar light 101 reflected by the reflector panel 102 is concentrated to the photovoltaic generator 103 and the temperature of the photovoltaic generator 103 is thereby raised. The heat generated in the photovoltaic generator 103 is transmitted to the heat exchange mechanism 105, that is, to the heat transport medium 121 in the portion of the cyclic conduit 120 being contacted with the photovoltaic generator 103. The heat transport medium 121 receives the heat from the photovoltaic generator 103 is pumped to the cold storage member 107 by the pump 122. In case the material other than water is filled in the cold storage member 107 as the cold storage material 112, the heat transport medium 121 flows through the pipes 118 in the cold storage member 107. In the cold storage member 107, the heat of the heat transport medium 121 flowing through the pipes 118 is transmitted to the cold storage material 112 and to the inner fins 115. Then, the heat transport medium 121 flows into the cyclic conduit 120. Thus, the heat is drawn from the photovoltaic generator 103 by the repetition of circulation of the heat transport medium 121 and the working fluid of the heat pipe loop 111.

Since the photovoltaic generator 103 is thus cooled, an efficiency of the photoelectric conversion of the photovoltaic generator 103 will not be degraded by the heat. Therefore, the electromotive force of the photovoltaic generation can be stabilized. In addition, in case the external temperature drops lower than the temperature of the cold storage material 112 in the cold storage member 107 in the nighttime, the heat of the cold storage material 112 is radiated through the radiation fins 108, and the cold storage material 112 is thereby cooled. The cold energy thus stored is utilized to cool the photovoltaic generator 103 performing the photovoltaic generation in the daytime.

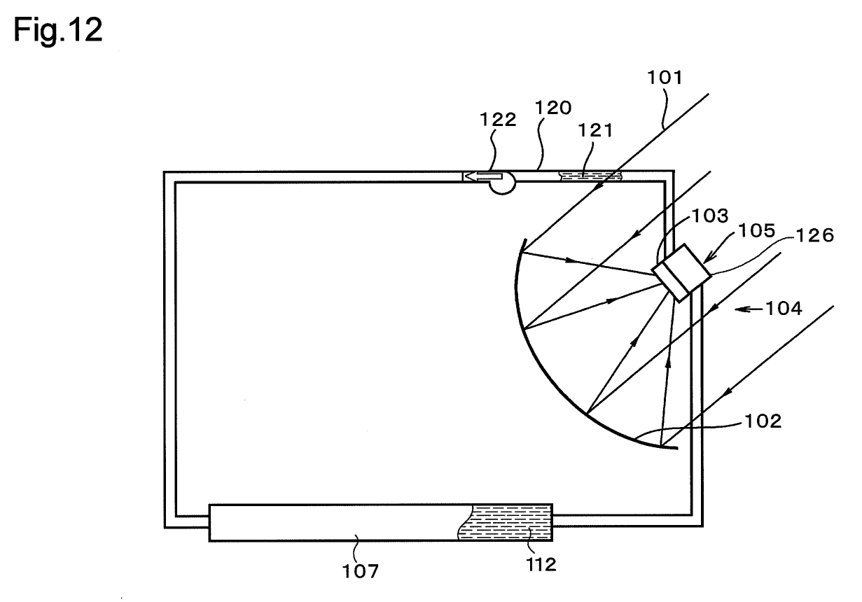

An alternative of the cooling system shown in FIGS. 10 and 11 is schematically shown in FIG. 12. As shown in FIG. 12, the photovoltaic generator 103 is arranged at the focal point of the reflector panel 102. According to the system shown in FIG. 12, the cold storage member 107 holding the cold storage material 112 is situated at the lowest elevation in the system, for example, the cold storage member 107 is placed on the ground. Here, the reflector panel 102 may be inclined with respect to the ground in accordance with the solar position. The cold storage member 107 and the photovoltaic generator 103 are connected through the cyclic conduit 120, and the pump 122 is arranged at an arbitrary position of the cyclic conduit 120. Therefore, the heat can be exchanged between the photovoltaic generator 103 and the cold storage member 107 by circulating the heat transport medium 121 in the cyclic conduit 120 by the pump 122. Accordingly, a portion of the cyclic conduit 120 contacted with the photovoltaic generator 103 functions as the heat exchange portion 105 of this example.

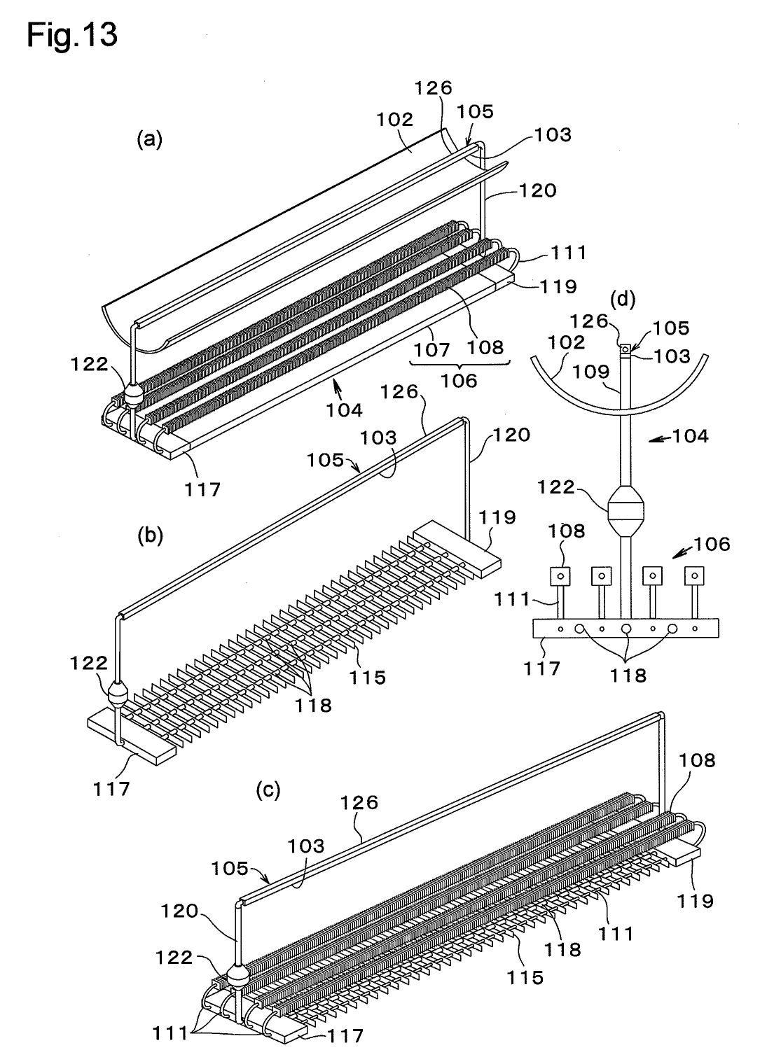

The system shown in FIG. 12 is depicted in more detail in FIG. 13. As shown in FIG. 13 (a), the photovoltaic generator 103 is arranged at the focal point of the reflector panel 102. As described, the cold storage member 107 holding the cold storage material 112 is situated at the lowest elevation of the system. The photovoltaic generator 103 and the cold storage member 107 are connected through the cyclic conduit 120, and the heat transport medium 121 is held in the cyclic conduit 120. In this example, the pump 122 for circulating the heat transport medium 121 in the cyclic conduit 122 is arranged in the vicinity of one of the end portions of the cyclic conduit 122. The pump 122 is driven by the electric energy generated by the photovoltaic generation. A plurality of arrays of radiation fins 108 are arranged on an upper face of the cold storage member 107. As will be explained in more detail with reference to FIG. 13 (c), each array of the fins 108 is connected with the inner space of the cold storage member 107 in a heat transmittable manner by a heat pipe loop 111 made of copper or copper alloy. Here, a thermosiphon loop may also be used instead of the heat pipe loop 111.

FIG. 13 (b) is a perspective view of the cold storage member 107. In case of using the phase change material other than water as the cold storage material 112, for example, in case of using ethylene glycol as the cold storage material 112, an additional pipe may be arranged penetrating through the cold storage member 107 for letting through the heat transport medium 121 without being mixed with the cold storage material 112. As shown in FIG. 13 (b), a plurality of internal fins 115 is juxtaposed to each other. Therefore, a plurality of pipes 118 for letting through the heat transport medium 121 are arranged in the cold storage member 107 while penetrating through the internal fins 115 in a heat transmittable manner. Both ends of the pipes 118 are individually connected with the end portion of the cyclic conduit 120 by the headers 117 and 119.

A relation between the radiation fins 108 and the internal fins 115 is shown in FIG. 13 (c). Here, the cold storage member 107 is omitted from FIG. 13 (c) for the sake of convenience. As shown in FIG. 13 (c), each array of the radiation fins 108 is connected with the inner fins 115 by the heat pipe loops 111 holding a working fluid therein. Here, as explained above, the heat pipe loops 111 are contacted with both of the fins 108 and 115 to transmit the heat thereof to the fins 108 and 115. Accordingly, a portion of the heat pipe loop 111 being contacted with the internal fins 115 functions as an evaporating portion, and a portion of the heat pipe loop 111 being contacted with the radiation fins 108 functions as a condensing portion. In addition, in order to circulate the working fluid in the heat pipe loop 111 by a capillary action, a wick may be provided in the heat pipe loop 111 according to need. For better understanding, a cross section of the system is shown in FIG. 13 (d).

Accordingly, the cold storage member 107 and the radiation fins 108 constitute the radiating mechanism 106 of this example, and a series of the elements transporting the heat from the photovoltaic generator 103 to radiate the heat from radiation fins 108, that is, the cyclic conduit 120, and the radiating mechanism 106 constitute the radiation cooling mechanism 104 of this example.

The solar light 101 reflected by the reflector panel 102 is concentrated to the photovoltaic generator 103 and the temperature of the photovoltaic generator 103 is thereby raised. The heat generated in the photovoltaic generator 103 is transmitted to the heat exchange mechanism 105, that is, to the heat transport medium 121 in the portion of the cyclic conduit 120 being contacted with the photovoltaic generator 103. The heat transport medium 121 receives the heat from the photovoltaic generator 103 is pumped to the cold storage member 107 by the pump 122. In case the material other than water is filled in the cold storage member 107 as the cold storage material 112, the heat transport medium 121 flows through the pipes 118 in the cold storage member 107. In the cold storage member 107, the heat of the heat transport medium 121 flowing through the pipes 118 is transmitted to the cold storage material 112 and to the inner fins 115. The heat thus transmitted to the cold storage material 112 and to the inner fins 115 is transported to the radiation fins 108 arranged on the upper face of the cold storage member 107, and radiated from the radiation fins 108 to the air. On the other hand, the heat transport medium 121 flowing through the pipes 118 then flows into the cyclic conduit 120. Thus, the heat is drawn from the photovoltaic generator 103 by the repetition of circulation of the heat transport medium 121 and the working fluid of the heat pipe loop 111.

Since the photovoltaic generator 103 is thus cooled, an efficiency of the photoelectric conversion of the photovoltaic generator 103 will not be degraded by the heat. Therefore, the electromotive force of the photovoltaic generation can be stabilized. In addition, in case the external temperature drops lower than the temperature of the cold storage material 112 in the cold storage member 107 in the nighttime, the heat of the cold storage material 112 is radiated through the radiation fins 108, and the cold storage material 112 is thereby cooled. The cold energy thus stored is utilized to cool the photovoltaic generator 103 performing the photovoltaic generation in the daytime.

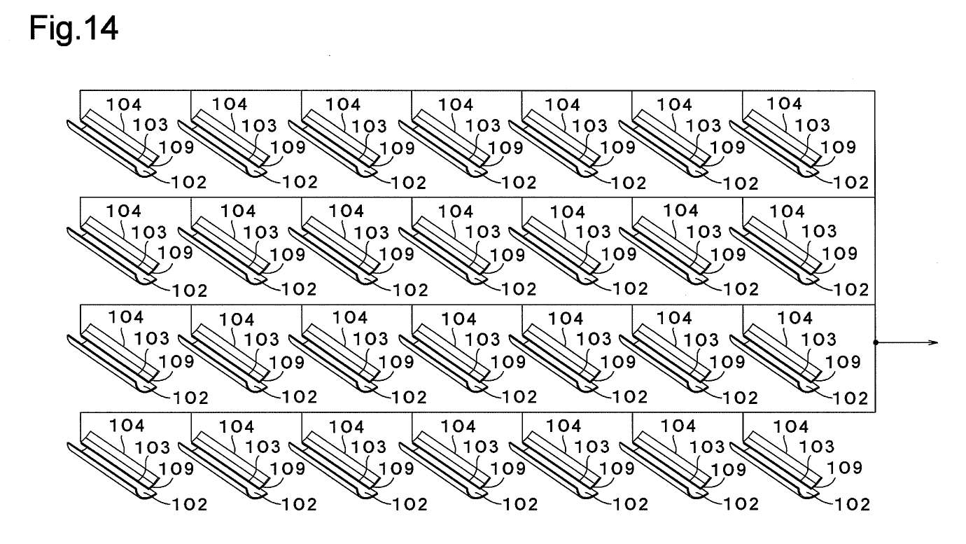

As shown in FIG. 14, a solar electric power station can be formed by combining concentrating photovoltaic generation systems, as described above, as a module. Here, a kind of the system to use as the module, and a number of the modules to form the solar electric power station may be changed arbitrarily according to need, for example, according to a desired output. In this case, each module may be thermally independent from other modules but connected electrically. This means that each module is capable of generating electric power independently. For this reason, in case some of the modules are in trouble, the remaining modules are allowed to carry out solar generation without being affected by the troubled modules. On the other hand, the troubled systems can be repaired while carrying out solar generation by the remaining systems.

Thus, the concentrating photovoltaic generation systems according to exemplary embodiments of the present invention are adapted to perform solar generation by collecting the solar light 101. Therefore, a number of the photovoltaic generator 103 to be used in the system can be minimized thereby reducing the cost of the generation system itself. Moreover, since concentrating photovoltaic generation systems according to exemplary embodiments of the present invention are adapted to radiate the heat of the photovoltaic generator 103 to the air thereby storing the cold energy, the photovoltaic generator 103 can be cooled without consuming the electric energy. This means that the generated energy can be outputted entirely. Further, the concentrating photovoltaic generation systems according to exemplary embodiments of the present invention are capable of generating without emitting carbon dioxide. Thus, exemplary concentrating photovoltaic generation systems according to the present invention are eco-friendly.

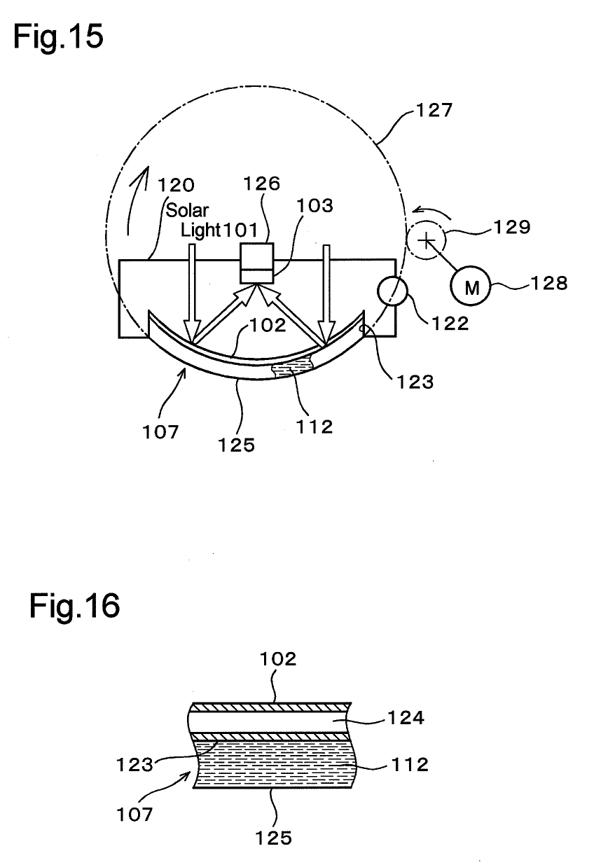

An example of a cooling system of the concentrating photovoltaic generation system according to the present invention is schematically shown in FIG. 15. As shown in FIG. 15, the photovoltaic generator 103 is arranged at the focal point of the reflector panel 102. A positional relation between the reflector panel 102 and the photovoltaic generator 103 may be fixed. Thus, according to the example shown in FIG. 15, the reflector panel 102 and the photovoltaic generator 103 may be supported by a frame not shown.

As shown in FIG. 15, the reflector panel 102 is arranged to face the sky. An orientation, in other words an angle of the reflector panel 102, is adjusted in accordance with the solar position by a tracking system such as a heliostat not shown. The cold storage member 107 is arranged radially outside of the reflector panel 102, i.e., a back face of the reflector panel 102 opposite to the face facing with photovoltaic generator 103. The cold storage member 107 comprises a container 123 holding the cold storage material 112 therein. The temperature of the cold storage material 112 is kept to low temperature, and the photovoltaic generator 103 is cooled by the cold storage material 112 kept to the low temperature.

The container 123 is a thin container formed integrally along the outer surface of the reflector panel 102. In other words, the reflector panel 102 is arranged on a radially inner face of the curved thin container 123 whose cross-section is parabolic. As shown in FIG. 16, in order to prevent the heat of the reflector panel 102 from being transmitted to the cold storage material 112, a heat-insulating layer 124 is interposed between the cold storage material 112 encapsulated in the container 123 and the reflector panel 102. An air layer filled with air, a vacuum layer whose inner space is evacuated, or other layers made of an appropriate heat-insulating material may be employed as the heat-insulating layer 124. Since the cold storage member 107 is thus formed on the radially outer surface of the reflector panel 102, the cold storage member 107 is shielded from the solar light 101 by the reflector panel 102 in case the reflector panel 102 is turned to expose the radially inner face thereof to the sun.

One of the surfaces of the cold storage member 107, that is, radially outer surface of the cold storage member 107 is painted black or the like to enhance its emissivity. That is, the outer surface of the cold storage member 107 functions as a radiation face 125 for cooling the cold storage material 112.

As described, the solar light is concentrated to the photovoltaic generator 103 and the temperature of the photovoltaic generator 103 is thereby raised. Therefore, in order to prevent such temperature rise of the photovoltaic generator 103, the generation system shown in FIG. 15 is structured to cool the photovoltaic generator 103. Specifically, a light receiving portion of the photovoltaic generator 103 is faced with the reflector panel 102, and a cooling jacket 126 is arranged on the opposite side of the light receiving portion. The cooling jacket 126 and the cold storage member 107 are connected through the cyclic conduit 120 filled with the heat transport medium such as water, and the pump 122 is provided on the cyclic conduit 120. The heat transport medium is circulated in the cyclic conduit 120 via the cooling jacket 126 by the pump 123 thereby transporting the heat of the photovoltaic generator 103 to the cold storage member 107 so as to cool the photovoltaic generator 103. In case both of the heat transport medium circulating in the cyclic conduit 120 and the cold storage material 112 in the cold storage member 107 are water, any specific pipe is not required for letting through the heat transport medium in the cold storage member 107. However, in case of using other material such as ethylene glycol as the cold storage material, the cyclic conduit 120 is extended to penetrate thorough the container 123 in a manner to exchange the heat between the heat transport medium flowing through and the cold storage material 112 in the container 123.

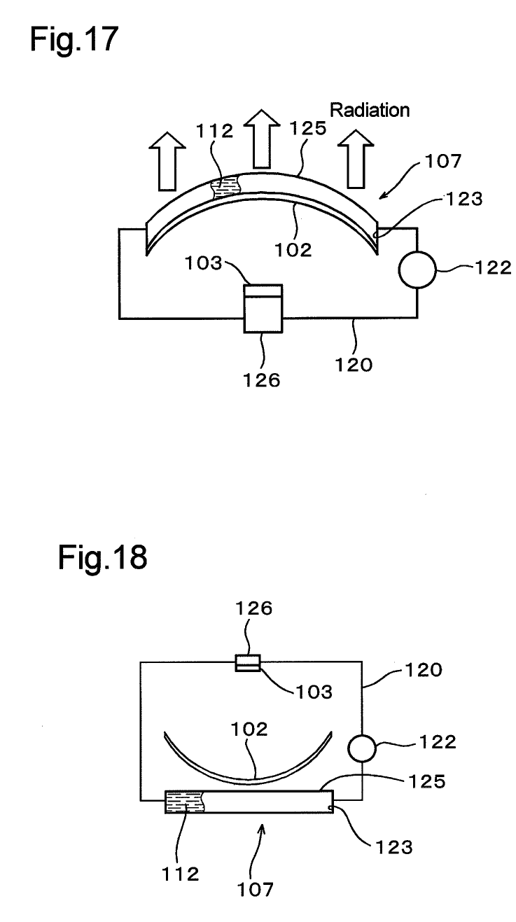

In addition, the generation system shown in FIG. 15 comprises a turnover mechanism to rotate the integrated reflector panel 102 and cold storage member 107. That is, the turnover mechanism is adapted to bring the radiation face 125 to face the sky instead of the reflector panel 102. The mechanism to be used as the turnover mechanism should not be limited to any specific mechanism. For example, in the example shown in FIG. 15, the frame holding the reflector panel 102, the cold storage member 107 and the photovoltaic generator 103 is adapted to rotate around a horizontal axis passing through the photovoltaic generator 103. As shown in FIG. 15, a ring gear 127 is attached to the frame in a manner to revolve around the horizontal axis, and a drive gear 129 meshing with the ring gear 129 is driven by a motor 128. Therefore, the reflector panel 102, the cold storage member 107 and the photovoltaic generator 103 are rotated around the horizontal axis together with the ring gear 127 by driving the motor 128. As a result, the cold storage member 107 is situated above the photovoltaic generator 103 and the reflector panel 102, as shown in FIG. 17. Since the radiation face 125 of the cold storage member is thus faced with the sky, the heat of the cold storage member 107 is radiated to the air in the nighttime, and the cold storage material 112 in the container 123 is thereby cooled.

When carrying out a solar generation by the system shown in FIG. 15, an angle of the reflector panel 102 is adjusted to be confronted with the sun. Collimated solar light shining on the reflector panel 102 is concentrated to the photovoltaic generator 103 situated at the focal point of the reflector panel 102, and the solar light, that is, the light energy is converted into electric energy by the photovoltaic generator 103. Thus, the photovoltaic generator 103 receives a large amount of strong solar light, and the solar light is partially absorbed by the photovoltaic generator 103. As a result, temperature of the photovoltaic generator 103 is raised. However, as described above, the heat-insulating layer 124 is interposed between the reflector panel 102 and the cold storage member 107 so that the cold storage member 107 is prevented from being heated by the solar light. The electric energy generated by the photovoltaic generator 103 is transmitted to an electric storage device not shown or to a predetermined portion. Here, the angle of the reflector panel 102 is adjusted successively in accordance with the solar position. Therefore, the solar light is concentrated to the reflector panel 102 constantly.

As mentioned above, the photovoltaic generator 103 is heated as a result of solar generation and heated also by the heat ray contained in the solar light. However, the heat transport medium cooled by the cold storage member 107 is supplied to the cooling jacket 126 integrated with the photovoltaic generator 103. Therefore, the photovoltaic generator 103 is prevented from temperature rise thereof. For this reason, the photovoltaic generator 103 is allowed to carry out the solar generation efficiently.

Temperature of the cold storage material 112 in the cold storage member 107 is raised gradually as cooling the photovoltaic generator 103. That is, in case of using a latent heat storage material as the cold storage material 112, the cold storage material 112 is melted gradually. When the latent heat storage material is melted completely, the temperature thereof is raised. The cooling system of the present invention is adapted to cool the heated cold storage material 112 by radiating the heat thereof in the nighttime. Specifically, the motor 128 is activated after the sun goes down below the horizon to rotate the reflector panel 102 and the cold storage member 107 integrated therewith. As a result, the cold storage member 107 is situated above the photovoltaic generator 103 and the reflector panel 102, as shown in FIG. 17. More specifically, the radiation face 125 of the cold storage member 107 is faced with the dark sky. As explained, the emissivity of the radiation face 125 is enhanced so that the heat of the cold storage member 107 is radiated from the radiation face 125, and the cold storage member 107 is thereby cooled. That is, the heat resulting from the solar generation carried out in the daytime is radiated to the air thereby cooling the cold storage material 112. This means that the cold storage material 112 can be cooled most efficiently under the clear night sky. If the temperature is low in the night, the cold storage member 107 is also cooled by the ambient air.

An achieving temperature of the cold storage material 112 thus cooled is substantially governed by an environment of the place where the system is installed. Therefore, in case of using the latent heat storage material as the cold storage material 112, it is preferable to select the latent heat storage material whose freezing point or the like is suitable for the installation site. An amount of solar light concentrated to the reflector panel 102 can be increased by enlarging the reflector panel 102. However, a heat amount heating the photovoltaic generator 103 is also increased in accordance with the increase of the solar light. Therefore, the size of the reflector panel 102 is limited by the heat amount heating the photovoltaic generator 103. Therefore, in case large amount of output is required, a number of units comprising the reflector panel 102 and the cold storage member 107 to be used is increased, and the photovoltaic generator 103 of those units are connected in series-parallel.

As explained, the cooling system of the present invention comprises the cold storage member for cooling the photovoltaic generator, and a principle of the present invention is to shield the cold storage member from the solar light by the reflector panel in the daytime, and to expose the cold storage member to the sky in the nighttime. Therefore, the configuration of the cooling system should not be limited to the configuration of the above-explained example shown in FIGS. 15 to 17.

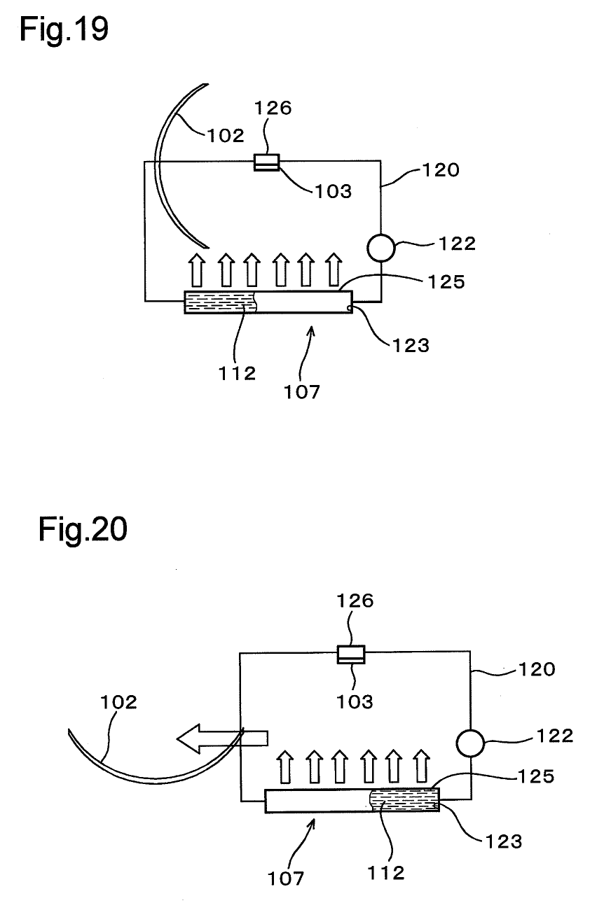

Here will be explained another example of the cooling system with reference to FIGS. 18 and 19. As shown in FIGS. 18 and 19, the reflector panel 102 and the cold storage member 107 are separated from each other, and adapted to be moved relative to each other. Specifically, the cold storage member 107 is situated on the back side of the reflector panel 102, that is, outside of the radially outer face of the reflector panel 102. As shown in FIGS. 18 and 19, width of the cold storage member 107 is narrower than that of the reflector panel 102. Therefore, the cold storage member 107 can be shielded from the solar light by the reflector panel 102 in case the reflector panel 102 is exposed to the solar light. In other words, the cold storage member 107 will not be exposed directly to the solar light. An upper face of the installed cold storage member 107, that is, the face of the cold storage member 107 faced with the sky serves as the radiation face 125.

The reflector panel 102 and the cold storage member 107 are moved integrally within the range of movement of the reflector panel 102 to track the solar position. However, the reflector panel 102 and the cold storage member 107 are moved relatively outside of the range of the movement of the reflector panel 102 to track the solar position. Specifically, the reflector panel 102 is rotated by the aforementioned mechanism comprising the ring gear, the drive gear and the motor, or by other suitable mechanisms to be displaced from the position where the cold storage member 107 is covered by the reflector panel 102. The mechanism for moving the reflector panel 102 corresponds to the displacing mechanism of the present invention. The remaining configuration is identical to those in the example shown in FIGS. 15 to 17, so further explanation will be omitted by allotting common reference numerals.

FIG. 18 shows a formation of the system to carry out the solar generation in the daytime. As shown in FIG. 18, the reflector panel 102 is situated between the cold storage member 107 and the photovoltaic generator 103. In this situation, the solar light is being reflected by the reflector panel 102 to be concentrated to the photovoltaic generator 103, and the photovoltaic generator 103 is generating electromotive force by the solar light concentrated thereto. On the other hand, the cold storage member 107 is being shielded from the solar light by the reflector panel 102. Thus, according to the example shown in FIG. 18, the cold storage member 107 will not be heated excessively during the solar generation. Therefore, the cold storage member 107 is allowed to cool the heat transport medium, and the photovoltaic generator 103 is cooled by the cooled heat transport medium.

FIG. 19 shows a formation of the system in the nighttime. As shown in FIG. 19, since the solar light is not shining on the reflector panel 102, the reflector panel 102 is displaced from the position above the cold storage member 107. Specifically, in FIG. 19, the reflector panel 102 is rotated 90 degrees, in other words, the reflector panel 102 is rotated to be situated perpendicular to the radiation face 125, on the outside of the cold storage member 107. Accordingly, the radiation face 125 of the cold storage member 107 is exposed to the sky. As a result, the heat is radiated from the radiation face 125 in case the whether is clear in the nighttime, and the cold storage member 107 is thereby cooled. That is, the cold energy for cooling the photovoltaic generator 103 in the daytime is stored.

Still another example of the cooling system, specifically, an example in which is the reflector panel 102 and the cold storage member 107 are moved relatively with each other in the horizontal direction is shown in FIG. 20. According to the example shown in FIG. 20, one of the reflector panel 102 and the cold storage member 107 is put on a not shown rail extending horizontally. Therefore, one of the reflector panel 102 and the cold storage member 107 is slid on the rail to be overlapped with each other and to be moved away from the other one. That is, FIG. 20 shows a formation of the system for the nighttime. In the example shown in FIG. 20, the reflector panel 102 is horizontally displaced away from the cold storage member 107, and the cold storage member 107 is therefore exposed to the sky.

As described, the width of the cold storage member 107 is narrower than that of the reflector panel 102. Therefore, the cold storage member 107 can be shielded from the solar light by the reflector panel 102 when they are overlapped. To the contrary, the radiation face 125 of the cold storage member 107 is exposed to the sky in the nighttime by moving the reflector panel 102 away from the position above the cold storage member 107, and the heat is radiated from the radiation face 125. Thus, the example shown in FIG. 20 is capable of cooling the photovoltaic generator 103 naturally so that the generation efficiency of the photovoltaic generator 103 can be improved.

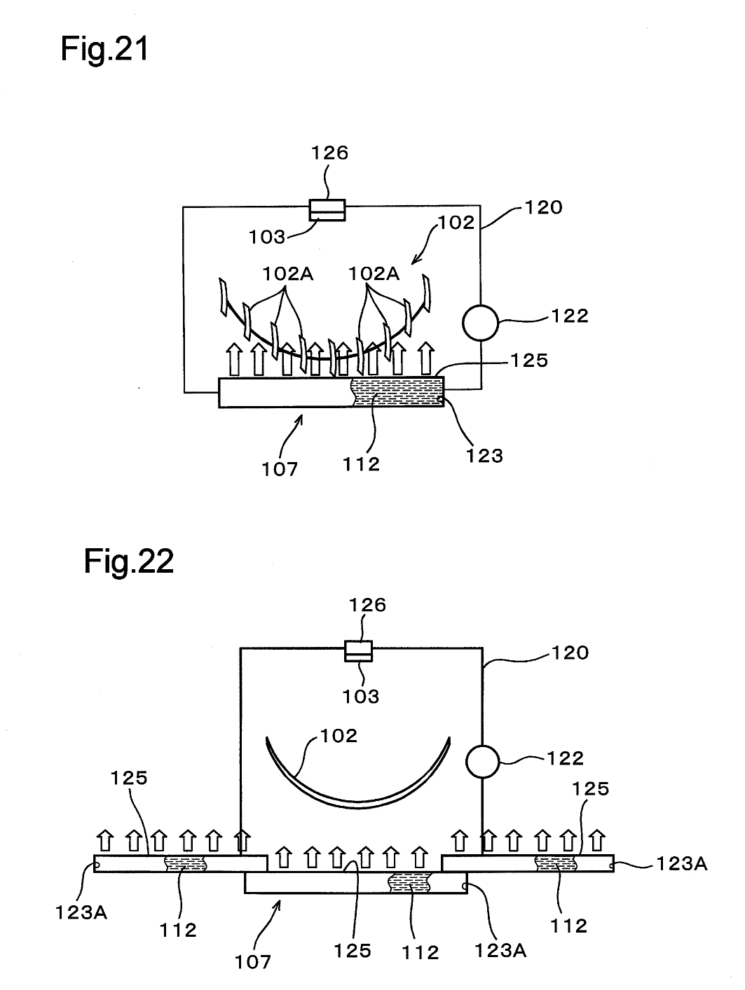

In an example shown in FIG. 21, the reflector panel 102 is divided into a plurality of slats 102A, and one of the faces of the slat 102A serves as a reflecting surface. Specifically, the slats 102A are arranged parallel to one another and adapted to be rotated individually around axes thereof. Therefore, the slats 102A are capable of reflecting the solar light when rotated to be closed, and letting thorough the solar light when rotated to be opened. In addition, the slats 102A are adapted to overlap adjacent edges thereof slightly on each other when closed. Therefore, the cold storage member 107 can be shielded entirely from the solar light by the closed slats 102A. In other words, the slats 102A are formed by cutting the reflector panel 102 longitudinally into plurality of pieces. Accordingly, the example shown in FIG. 21 is provided with a mechanism not shown for rotating the plurality of slats 102A on its axes, and this mechanism also corresponds to the displacing mechanism of the present invention.

Therefore, when the slats 102A are rotated to be vertical, clearances are created between each adjoining slat 102A, and the radiation face 125 of the cold storage member 107 is exposed to the sky. To the contrary, when the slats 102A are rotated to be closed, the adjoining edges of the slats 102A are overlapped on each other so that the solar light is reflected toward the photovoltaic generator 103. That is, the solar light is reflected by the closed slats 102A without penetrating through the closed slats 102A, and the cold storage member 107 is shielded from the solar light completely by the closed slat 102A, i.e., by the reflector panel 102. Thus, the example shown in FIG. 21 is also capable of cooling the photovoltaic generator 103 naturally so that the generation efficiency of the photovoltaic generator 103 can be improved. In addition, according to the example shown in FIG. 21, no special space for displacing the reflector panel 102 from the position above the cold storage member 107 is required. Therefore, the system can be downsized entirely.

An example shown in FIG. 22 comprises a plurality of containers 123A. Width of the each container 123A is substantially identical to that of the reflector panel 102, and each container 123A holds the cold storage material 112 therein. Those containers 123A are adapted to slide horizontally therefore, the containers 123A are allowed not only to be arranged in a horizontal row, but also to be overlapped on each other. In addition, each container 123A is adapted to store the cold energy and to output the cold energy therefrom. Accordingly, the example shown in FIG. 22 is provided with a mechanism not shown for sliding the containers 123A to arrange the containers 123A in a row, and to overlap the containers 123A. This mechanism for sliding the containers 123A also corresponds to the displacing mechanism of the present invention.

Therefore, when the containers 123A are expanded wider than the reflector panel 102 in the nighttime, portions of the radiation faces 125 outside of the reflector panel 102 are exposed to the dark sky. As a result, the heat of the cold storage materials 112 in the containers 123A radiated from the radiation faces 125, and the cold storage materials 112 are thereby cooled. The cold storage materials 112 in the containers 123A are also cooled by the air. To the contrary, in case the containers 123A are overlapped on each other underneath the reflector panel 102, the containers 123A are shielded from the solar light by the reflector panel 102 so that the cold storage materials 112 in the containers 123A will not be heated excessively by the solar light. Thus, the example shown in FIG. 22 is also capable of cooling the photovoltaic generator 103 naturally so that the generation efficiency of the photovoltaic generator 103 can be improved. In addition, according to the example shown in FIG. 21, an amount of the cold storage material 112 can be increased. Therefore, a cooling capacity to cool the photovoltaic generator 103 can be enhanced so that the generation efficiency of the photovoltaic generator 103 can be improved.

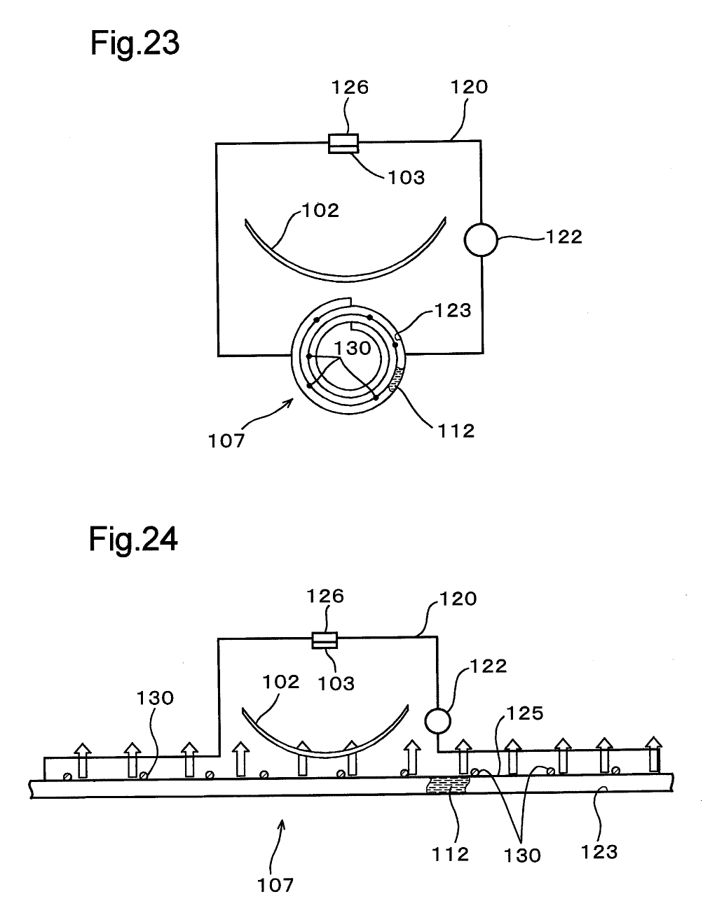

An alternative of the example shown in FIG. 22, that is, another example of altering the width of the cold storage member 107 to selectively expose the radiation face 125 thereof to the sky is shown in FIGS. 23 to 26. According to the example shown in FIGS. 23 and 24, the container 123 of the cold storage member 107 is made of flexible material such as a rubber sheet or a waterproof sheet. Therefore, the cold storage member 107 can be rolled into a cylinder as shown in FIG. 23, and expanded to be a flat sheet as shown in FIG. 24. On an upper face of the cold storage member 107, in other words, on an inner face of the cold storage member 107, a plurality of pipes 130 for letting through the heat transport medium are arranged in parallel with each other and in parallel with an axis to be rolled. Those pipes 130 are individually communicated with the cyclic conduit 120, therefore, the heat can be exchanged between the heat transport medium such as cold water and the cold storage material 112 in the container 123.

As mentioned above, the rolled container 123 is shown in FIG. 23, and the width of the cold storage member 107 situated underneath the reflector panel 102 is reduced narrower than that of the reflector panel 102. Therefore, the cold storage member 107 is shielded from the solar light when carrying out the solar generation in the daytime. In this situation, the solar light is concentrated to the photovoltaic generator 103 and the temperature of the photovoltaic generator 103 is thereby raised. However, the heat of the photovoltaic generator 103 is transported to the cold storage member 107 by circulating the heat transport medium through the cyclic conduit 120 and the pipes 130. As a result, the photovoltaic generator 103 is cooled so that the generation efficiency thereof can be maintained preferably.

In night time, the container 123 is expanded to be a flat sheet as shown in FIG. 24. In order to unroll and expands the container 123 or the cold storage member 107, the example shown in FIGS. 23 and 24 also comprises the displacing mechanism not shown for unrolling and expanding the container 123 or the cold storage member 107. In case the container 123 is expanded the radiation face 125 formed on the upper face of the container 123 is exposed to the sky except for the portion underneath the reflector panel 102, and the heat is radiated from the exposed portion of the radiation face 125. Thus, the cold storage material 112 is cooled in the nighttime, and the cold energy for cooling the photovoltaic generator 103 is thereby stored.

Accordingly, the example shown in FIGS. 23 and 24 is capable of radiating the heat of the cold storage material 112 and cooling the photovoltaic generator 103 by the cold storage material 112 thus cooled. Therefore, the photovoltaic generator 103 is allowed to perform solar generation efficiently without requiring any special energy for cooling the photovoltaic generator 103.

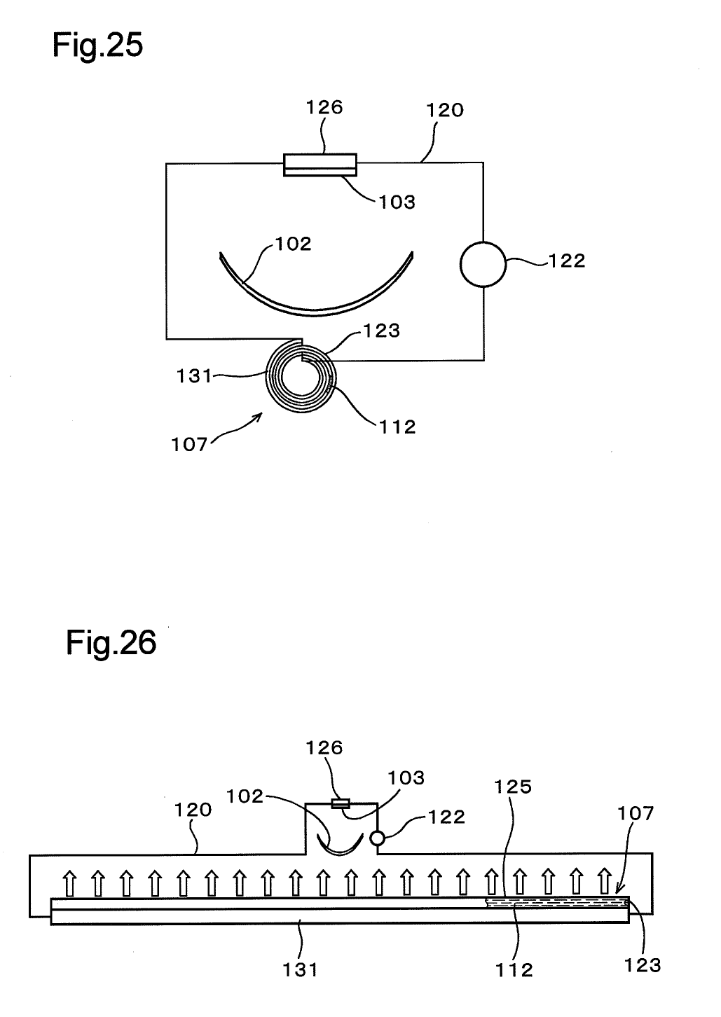

An example shown in FIGS. 25 and 26 further comprises a water jacket 131 formed integrally with a lower face of the flexible container 123. The water jacket 131 is also made of flexible material so that the water jacket 131 can also be rolled into a cylinder. As shown in FIGS. 25 and 26, both ends of the water jacket 131 are communicated with the cyclic conduit 120.

As shown in FIG. 25, the width of the integrated rolled container 123 and the water jacket 131 situated underneath the reflector panel 102 is reduced narrower than that of the reflector panel 102. Therefore, the cold storage member 107 is shielded from the solar light when carrying out the solar generation in the daytime. In this situation, the solar light is concentrated to the photovoltaic generator 103 and the temperature of the photovoltaic generator 103 is thereby raised. However, the heat of the photovoltaic generator 103 is transported to the cold storage member 107 by circulating the heat transport medium through the cyclic conduit 120 and the water jacket 131. As a result, the photovoltaic generator 103 is cooled so that the generation efficiency thereof can be maintained preferably.

In night time, the container 123 and the water jacket 131 are expanded to be a flat sheet as shown in FIG. 26. In order to unroll and expands the container 123 and the water jacket 131, the example shown in FIGS. 25 and 26 also comprises the displacing mechanism not shown for unrolling and expanding the container 123 and the water jacket 131. In case the container 123 is expanded, the radiation face 125 formed on the upper face of the container 123 is exposed to the sky except for the portion underneath the reflector panel 102, and the heat is radiated from the exposed portion of the radiation face 125. Thus, the cold storage material 112 is cooled in the nighttime, and the cold energy for cooling the photovoltaic generator 103 is thereby stored.

Accordingly, the example shown in FIGS. 25 and 26 is capable of radiating the heat of the cold storage material 112 and cooling the photovoltaic generator 103 by the cold storage material 112 thus cooled. Therefore, the photovoltaic generator 103 is allowed to perform solar generation efficiently without requiring any special energy for cooling the photovoltaic generator 103.

Although the above exemplary embodiments of the present invention have been described, it will be understood by those skilled in the art that the present invention should not be limited to the described exemplary embodiments, but that various changes and modifications can be made within the spirit and scope of the present invention.

What is claimed is:

1. A concentrating photovoltaic generation system, comprising:
a photovoltaic generator for converting solar light into electric power;
a reflector panel for concentrating the solar light onto the photovoltaic generator; and
a radiation cooling mechanism for radiating heat to the air thereby storing cold energy, and for cooling the photovoltaic generator by the stored cold energy.

2. The concentrating photovoltaic generation system according to claim 1, wherein:
the reflector panel comprises a reflecting surface for concentrating the solar light onto the photovoltaic generator; and
the radiation cooling mechanism comprises:
a heat exchange mechanism which is in contact with the photovoltaic generator, such that heat is exchangeable therebetween,
a radiating mechanism for radiating heat therefrom to the air, and
a heat transport means for transporting heat between the heat exchange mechanism and the radiating mechanism.

3. The concentrating photovoltaic generation system according to claim 2, wherein:
the radiating mechanism comprises at least one radiation fin for radiating heat transported thereto from the heat exchange mechanism.

4. The concentrating photovoltaic generation system according to claim 2, wherein:
the radiating mechanism comprises a cold storage member for storing cold energy therein, and at least one radiating fin for radiating heat transported from the cold storage member to the air.

5. The concentrating photovoltaic generation system according to claim 4, wherein:
the reflector panel is disposed between the photovoltaic generator and the cold storage member.

6. The concentrating photovoltaic generation system according to claim 4, wherein:
the cold storage member is situated radially outside of the reflector panel, and the heat transport means comprises one of a thermosiphon and a heat pipe for transporting heat between the cold storage member and the heat exchange mechanism.

7. The concentrating photovoltaic generation system according to claim 6, wherein:
the at least one radiation fin is situated on a radially outer surface of the cold storage member; and
the at least one radiation fin and the cold storage member are connected to each other by one of a thermosiphon and a heat pipe.

8. The concentrating photovoltaic generation system according to claim 7, further comprising:
a cold storage material disposed in the cold storage member; and
at least one internal fin arranged in the cold storage member;
wherein the at least one internal fin and the at least one radiation fin are connected to each other via the one of the thermosiphon and the heat pipe which connects the radiation fin to the cold storage member.

9. The concentrating photovoltaic generation system according to claim 8, further comprising:
a heat spreader plate, which is arranged in the cold storage member, for dispersing heat transmitted thereto from the heat exchange mechanism through the cold storage material.

10. The concentrating photovoltaic generation system according to claim 6, further comprising:
a cold storage material disposed in the cold storage member; and
at least one internal fin arranged in the cold storage member;
wherein the at least one internal fin and the at least one radiation fin are connected to each other via the one of the thermosiphon and the heat pipe.

11. The concentrating photovoltaic generation system according to claim 10, further comprising:
a plurality of pipes penetrating thorough the cold storage member and in contact with the cold storage material;
a first header connecting first end portions of the plurality of pipes with the heat transport means; and
a second header connecting second end portions of the plurality of pipes with the heat transport means.

12. The concentrating photovoltaic generation system according to claim 11, wherein:
the plurality of pipes penetrate through the at least one internal fin in a manner such that heat is exchangeable therebetween.

13. The concentrating photovoltaic generation system according to claim 6, further comprising:
a cold storage material disposed in the cold storage member; and
a heat spreader plate, which is arranged in the cold storage member, for dispersing heat transmitted thereto from the heat exchange mechanism through the cold storage material.

14. The concentrating photovoltaic generation system according to claim 13, further comprising:
one of a thermosiphon loop and a heat pipe loop having a first portion thereof which penetrates through the cold storage member and a second portion thereof which is exposed to the air;
wherein the at least one radiation fin is attached to the second portion.

15. The concentrating photovoltaic generation system according to claim 4, wherein:
a first side of the photovoltaic generator faces the cold storage portion and a second side of the photovoltaic generator faces the reflector panel; and
the heat transport means comprises one of a thermosiphon and a heat pipe for transporting a heat between the cold storage member and the heat exchange mechanism.

16. The concentrating photovoltaic generation system according to claim 15, further comprising:
a cold storage material disposed in the cold storage member; and
at least one internal fin arranged in the cold storage member;
wherein the at least one internal fin and the at least one radiation fin are connected by one of a thermosiphon and a heat pipe.

17. The concentrating photovoltaic generation system according to claim 4, wherein:
the cold storage member is situated radially outside of the reflector panel;
the heat transport means comprises
a cyclic conduit connecting the heat exchange mechanism and the radiating mechanism,
a heat transport medium disposed in the cyclic conduit, and
a pump, which is arranged on the cyclic conduit for circulating the heat transport medium in the cyclic conduit.

18. The concentrating photovoltaic generation system according to claim 17, further comprising:
a cold storage material disposed in the cold storage member;
a plurality of pipes penetrating thorough the cold storage member and in contact with the cold storage material;
a first header connecting first end portions of the plurality of pipes with the heat transport means;
a second header connecting second end portions of the plurality of pipes with the heat transport means;
a heat transport medium disposed in the plurality of pipes and in the first and second headers; and
wherein the heat transport means is adapted to circulate the heat transport medium through the cyclic conduit via one of the first header, the plurality of pipes and the second header.

19. The concentrating photovoltaic generation system according to claim 18, further comprising:
at least one internal fin arranged in the cold storage member; and
wherein the plurality of pipes penetrate through the at least one internal fin and contact the at least one internal fin such that heat is exchangeable therebetween.

20. The concentrating photovoltaic generation system according to claim 1, wherein the radiation cooling mechanism comprises:
a cold storage member comprising a radiation face radiating the heat therefrom;
a cyclic conduit for cooling the photovoltaic generator by circulating a heat transport medium between the cold storage member and the photovoltaic generator; and
a displacement mechanism for moving at least one of the reflector panel and the cold storage member into a first position in which the reflector panel blocks the radiation face as viewed from a predetermined direction and a second position in which the reflector panel does not block the radiation face as viewed from the predetermined direction.

21. The concentrating photovoltaic generation system according to claim 20, wherein:
the reflector panel comprises a reflecting surface for concentrating the solar light onto the photovoltaic generator;
the cold storage member is formed integrally with a radially outer face of the reflector panel;
the radiation face is formed on a radially outer face of the cold storage member; and
the displacement mechanism comprises a mechanism for moving an integrated unit comprising the reflector panel and the cold storage member into the first position in which the reflecting surface is exposed as viewed from the predetermined direction, and into the second position in which the radiation face is exposed as viewed from the predetermined direction.

22. The concentrating photovoltaic generation system according to claim 21, further comprising:
a heat-insulating layer disposed between the reflector panel and the cold storage member.

23. The concentrating photovoltaic generation system according to claim 21, wherein:
the heat-insulating layer comprises an air layer and a vacuum layer; and
the cold storage member comprises a latent heat storage material for storing cold energy in the form of latent heat resulting from a phase change thereof.

24. The concentrating photovoltaic generation system according to claim 20, wherein:
the reflector panel comprises a reflecting surface for concentrating the solar light onto the photovoltaic generator;
the cold storage member is situated radially outside of the reflector panel;
the radiation face is formed on a face of the cold storage member facing the predetermined direction in the first position; and
the displacement mechanism comprises a mechanism for moving the reflector panel relative to the cold storage member.

25. The concentrating photovoltaic generation system according to claim 24, further comprising:
a latent heat storage material for storing cold energy in the form of latent heat resulting from a phase change thereof.

26. The concentrating photovoltaic generation system according to claim 20, wherein:
the reflector panel comprises a plurality of slats which are each rotatable;
the displacement mechanism comprises a mechanism for rotating the slats, such that in the second position the radiation face of the cold storage member is exposed between the slats, as viewed from the predetermined direction; and
the system further comprising a latent heat storage material for storing cold energy in the form of latent heat resulting from a phase change thereof.

27. The concentrating photovoltaic generation system according to claim 20, wherein:
the cold storage member is adaptable between a first width thereof which is narrower than a width of the reflector panel, and a second width thereof which is wider than the width of the reflector panel; and
the displacement mechanism comprises a mechanism for changing the width of the cold storage member to the first width in the first position and to the second width in the second position.

28. The concentrating photovoltaic generation system according to claim 25, further comprising:
a latent heat storage material for storing cold energy in the form of latent heat resulting from a phase change thereof.

29. A concentrating photovoltaic generation system, comprising:
a thermoelectric conversion element for converting heat of solar light into electric power;
a heated portion in contact with the thermoelectric conversion element such that heat is transmittable therebetween;
a reflector panel for concentrating the solar light onto the heated portion; and
a radiation cooling mechanism for radiating heat to the air thereby storing cold energy, and for cooling the thermoelectric conversion element by the stored cold energy.

30. The concentrating photovoltaic generation system according to claim 29, wherein:
the reflector panel comprises a reflecting surface for concentrating the solar light onto the heated portion; and
the radiation cooling mechanism comprises
a heat exchange mechanism which is in contact with the thermoelectric conversion element such that heat is exchangeable therebetween,
a radiating mechanism for radiating heat therefrom to the air, and
a heat transport means for transporting heat between the heat exchange mechanism and the radiating mechanism.

31. The concentrating photovoltaic generation system according to claim 30, wherein:
the radiating mechanism comprises a cold storage member for storing cold energy therein, and at least one radiating fin for radiating heat transported from the cold storage member to the air.

32. The concentrating photovoltaic generation system according to claim 31, wherein the reflector panel is disposed between the thermoelectric conversion element and the cold storage member.

33. The concentrating photovoltaic generation system according to claim 31, wherein:
the cold storage member is situated radially outside of the reflector panel; and
the heat transport means comprises one of a thermosiphon and a heat pipe for transporting the heat between the cold storage member and the heat exchange mechanism.

34. The concentrating photovoltaic generation system according to claim 33, wherein:
the at least one radiation fin is situated on a radially outer surface of the cold storage member; and
the at least one radiation fin and the cold storage member are connected to each other by one of a thermosiphon and a heat pipe.
